(19) United States
(12) Patent Application Publication
(10) Pub. No.: US 2026/0004860 A1
(43) Pub. Date: Jan. 1, 2026

(54) STORAGE DEVICE AND OPERATING METHOD THEREOF

(71) Applicant: SK hynix Inc., Gyeonggi-do (KR)

(72) Inventors: Changhyun LEE, San Jose, CA (US); Paing Z. HTET, San Jose, CA (US); Dengtao ZHAO, San Jose, CA (US); Kyeongran YOO, San Jose, CA (US); Sung-Taeg KANG, San Jose, CA (US); Jungdal CHOI, San Jose, CA (US)

(21) Appl. No.: 18/916,614

(22) Filed: Oct. 15, 2024

Related U.S. Application Data
(60) Provisional application No. 63/665,403, filed on Jun. 28, 2024.

(51) Int. Cl. G11C 16/34; G11C 16/10

(52) U.S. Cl. CPC G11C 16/3459; G11C 16/102

(57) ABSTRACT

A storage device includes a group of non-volatile memory cells, page buffers coupled to the non-volatile memory cells and a control circuit. The control circuit performs one or more program loops on the group according to program data loaded on the page buffers, each of the program loops include a series of consecutive program pulse application operations and a series of consecutive verification operations.

### BACKGROUND

### 1. Field

Embodiments of the present invention relate to a storage device and an operating method thereof.

### 2. Description of the Related Art

A storage system stores data in response to a request from a host system such as a computer, smartphone, or smart pad. An example of a storage system is a system configured to store data in a semiconductor memory, especially in a nonvolatile memory, such as a solid-state drive (SSD) or a memory card.

A storage system includes a storage device configured to store data and a controller configured to control the storage device. Generally, a storage device can be volatile or non-volatile. Examples of a non-volatile storage device are Read Only Memory (ROM), Programmable ROM (PROM), Electrically Programmable ROM (EPROM), Electrically Erasable and Programmable ROM (EEPROM), flash memory, Phase-change RAM (PRAM), Magnetic RAM (MRAM), Resistive RAM (RRAM), and Ferroelectric RAM (FRAM).

### SUMMARY

In an embodiment of the present invention, a storage device may include a group of non-volatile memory cells, page buffers coupled to the non-volatile memory cells and a control circuit. The control circuit may perform one or more program loops on the group according to program data loaded on the page buffers, each of the program loops including a series of consecutive program pulse application operations and a series of consecutive verification operations. The control circuit may apply, during each of the series of consecutive program pulse application operations in each of the program loops, a selected program pulse to one or more non-volatile memory cells under a program-permission mode within the group while program-inhibiting remaining non-volatile memory cells under a program-inhibition mode within the group. The selected program pulse may be one among a series of consecutive program pulses to be applied to the group during the program pulse application operation. The control circuit may further determine, in between current and subsequent ones among the series of consecutive program pulse application operations, a selected one of the non-volatile memory cells as under the program-permission mode or the program-inhibition mode for the subsequent program pulse application operation by updating current program data currently staying loaded on a corresponding one of the page buffers for the current program pulse application operation. The control circuit may update the current program data by performing a logical operation on the current program data and reference data, which represents a target program level corresponding to a program pulse to be applied during the subsequent program pulse application operation.

The levels of the program pulses may sequentially step up by an incremental step over the respective program loops.

The control circuit may perform, during each of the program loops, the series of consecutive program pulse application operations by consecutively applying respective program pulses to the group, levels of the program pulses sequentially stepping up by an incremental step over the respective program pulse application operations. The control circuit may perform, during each of the program loops, the series of consecutive verification operations by consecutively applying respective verification pulses to the group, levels of the verification pulses sequentially stepping up by an incremental step over the respective verification operations.

The control circuit may determine the selected memory cell as under the program-permission mode when a current program level is equal to the target program level as a result of the logical operation. The current program level may be represented by the current program data.

The control circuit may determine the selected memory cell as under the program-permission mode when a current program level is higher than the target program level as a result of the logical operation. The current program level is represented by the current program data.

The control circuit may further perform, when one of the non-volatile memory cells is verified as programmed during a current one of the program loops, the series of consecutive program pulse application operations on the verified non-volatile memory cells while keeping the verified memory cell under the program-inhibition mode for subsequent program loops following the current program loop among the program loops.

The control circuit may further exclude, when one of the non-volatile memory cells is verified as programmed during a previous one of the program loops, the series of consecutive program pulse application operations on the verified memory cell during a current program loop subsequent to the previous program loop.

The control circuit may further perform again, when the verified memory cell is further verified as under-programmed during the current program loop, the series of consecutive program pulse application operations on the verified memory cell during a subsequent program loop following the current program loop.

The control circuit may further exclude, when one of the non-volatile memory cells is verified as programmed during a current one of the program loops, the series of consecutive verification operations on the verified memory cell during subsequent program loops following the current program loop among the program loops.

The control circuit may perform, during each of the program loops, the series of consecutive program pulse application operations by consecutively applying respective program pulses to the group, levels of the program pulses sequentially stepping down by a decremental step over the respective program pulse application operations. The control circuit may perform, during each of the program loops, the series of consecutive verification operations by consecutively applying respective verification pulses to the group, levels of the verification pulses sequentially stepping up by an incremental step over the respective verification operations.

The control circuit may determine the selected memory cell as under the program-permission mode when a current program level is revealed as equal to the target program level as a result of the logical operation. The current program level may be represented by the current program data.

The control circuit may determine the selected memory cell as under the program-permission mode when a current program level is higher than the target program level as a result of the logical operation. The current program level is represented by the current program data.

The control circuit may further perform, when one of the non-volatile memory cells is verified as programmed during a current one of the program loops, the series of consecutive program pulse application operations on the verified non-volatile memory cells while keeping the verified memory cell under the program-inhibition mode for subsequent program loops following the current program loop among the program loops.

The control circuit may further exclude, when one of the non-volatile memory cells is verified as programmed during a previous one of the program loops, the series of consecutive program pulse application operations on the verified memory cell during a current program loop subsequent to the previous program loop.

The control circuit may further perform again, when the verified memory cell is further verified as under-programmed during the current program loop, the series of consecutive program pulse application operations on the verified memory cell during a subsequent program loop following the current program loop.

The control circuit may further exclude, when one of the non-volatile memory cells is verified as programmed during a current one of the program loops, the series of consecutive verification operations on the verified memory cell during subsequent program loops following the current program loop among the program loops.

In an embodiment of the present invention, a storage device may include a group of non-volatile memory cells, page buffers coupled to the non-volatile memory cells and a control circuit. The control circuit may perform a (T−1)^{th} step program process on the group, T being a natural number of two (2) or greater; and perform a T^{th} step program process on the group upon completion of the (T−1)^{th} step program process. The T^{th} step program process may include one or more program loops on the group according to program data loaded on the page buffers, each of the program loops including a series of consecutive program pulse application operations and a series of consecutive verification operations. The control circuit may apply, during each of the series of consecutive program pulse application operations in each of the program loops, a selected program pulse to one or more non-volatile memory cells under a program-permission mode within the group while program-inhibiting remaining non-volatile memory cells under a program-inhibition mode within the group. The selected program pulse may be one among a series of consecutive program pulses to be applied to the group during the program pulse application operation. The control circuit may further determine, in between current and subsequent ones among the series of consecutive program pulse application operations, a selected one of the non-volatile memory cells as under the program-permission mode or the program-inhibition mode for the subsequent program pulse application operation by updating current program data currently staying loaded on a corresponding one of the page buffers for the current program pulse application operation. The control circuit may update the current program data by performing a logical operation on the current program data and reference data, which represents a target program level corresponding to a program pulse to be applied during the subsequent program pulse application operation.

The levels of the program pulses may sequentially step up by an incremental step over the respective program loops.

The control circuit may perform, during each of the program loops, the series of consecutive program pulse application operations by consecutively applying respective program pulses to the group, levels of the program pulses sequentially stepping up by an incremental step over the respective program pulse application operations. The control circuit may perform, during each of the program loops, the series of consecutive verification operations by consecutively applying respective verification pulses to the group, levels of the verification pulses sequentially stepping up by an incremental step over the respective verification operations.

The control circuit may determine the selected memory cell as under the program-permission mode when a current program level is revealed as equal to the target program level as a result of the logical operation. The current program level may be represented by the current program data.

The control circuit may determine the selected memory cell as under the program-permission mode when a current program level is higher than the target program level as a result of the logical operation. The current program level may be represented by the current program data.

The control circuit may further perform, when one of the non-volatile memory cells is verified as programmed during a current one of the program loops, the series of consecutive program pulse application operations on the verified non-volatile memory cells while keeping the verified memory cell under the program-inhibition mode for subsequent program loops following the current program loop among the program loops.

The control circuit may further exclude, when one of the non-volatile memory cells is verified as programmed during a previous one of the program loops, the series of consecutive program pulse application operations on the verified memory cell during a current program loop subsequent to the previous program loop.

The control circuit may further perform again, when the verified memory cell is further verified as under-programmed during the current program loop, the series of consecutive program pulse application operations on the verified memory cell during a subsequent program loop following the current program loop.

The control circuit may further exclude, when one of the non-volatile memory cells is verified as programmed during a current one of the program loops, the series of consecutive verification operations on the verified memory cell during subsequent ones to the current program loop among the program loops.

The control circuit may perform, during each of the program loops, the series of consecutive program pulse application operations by consecutively applying respective program pulses to the group, levels of the program pulses sequentially stepping down by a decremental step over the respective program pulse application operations. The control circuit may perform, during each of the program loops, the series of consecutive verification operations by consecutively applying respective verification pulses to the group, levels of the verification pulses sequentially stepping up by an incremental step over the respective verification operations.

The control circuit may determine the selected memory cell as under the program-permission mode when a current program level is revealed as equal to the target program level as a result of the logical operation. The current program level may be represented by the current program data.

The control circuit may determine the selected memory cell as under the program-permission mode when a current program level is higher than the target program level as a result of the logical operation. The current program level may be represented by the current program data.

The control circuit may further perform, when one of the non-volatile memory cells is verified as programmed during a current one of the program loops, the series of consecutive program pulse application operations on the verified non-volatile memory cells while keeping the verified memory cell under the program-inhibition mode for subsequent program loops following the current program loop among the program loops.

The control circuit may further exclude, when one of the non-volatile memory cells is verified as programmed during a previous one of the program loops, the series of consecutive program pulse application operations on the verified memory cell during a current program loop subsequent to the previous program loop.

The control circuit may further perform again, when the verified memory cell is further verified as under-programmed during the current program loop, the series of consecutive program pulse application operations on the verified memory cell during a subsequent program loop following the current program loop.

The control circuit may further exclude, when one of the non-volatile memory cells is verified as programmed during a current one of the program loops, the series of consecutive verification operations on the verified memory cell during subsequent program loops following the current program loop among the program loops.

The (T−1)^{th} step program process includes one or more conventional program loops each including a single program pulse application operation and one or more verification operation according to an incremental step pulse program (ISPP) scheme.

The (T−1)^{th} step program process may include storing a value of j^{th} program level when a selected one of the non-volatile memory cells is verified as programmed for a j^{th} program level during the conventional program loops. “j” may be a natural number ranging from one (1) to J, “J” being a maximum number of program states, to which the non-volatile memory cells within the group are supposed to belong during the (T−1)^{th} step program process.

The T^{th} step program process may include determining, during the series of consecutive program pulse application operations within a 1^{st} one of the plural program loops, a program level of each of the series of consecutive program pulses based on the J number of stored program levels according to a following equation group 1:

$$Vpgm\_ 2 step\_start for P 1 = Vpgm\_ 1 step\_stored \_E + offset\_ 1 \qquad [ Equation group 1 ]$$

$$Vpgm\_ 2 step\_start \_even ( even = 2 * j ) for even Ps = Vpgm\_ 1 step\_stored {\_j}^{th} + offset\_even$$

$$Vpgm\_ 2 step\_start \_odd ( odd = 2 * j + 1 ) for odd Ps = Vpgm\_ 1 step\_stored {\_j}^{th} + offset\_odd$$

$$offset\_even \leq offset\_odd ,$$

wherein:
“Vpgm_2step_start for P1” represents the program level of a program pulse to be applied to cells of a first program state during the 1^{st} program loop,
“Vpgm_1step_stored_E” represents a program level corresponding to an erase state during the (T−1)^{th} step program process,
“offset_1” represents an offset voltage level for the first program state at the 1^{st} program loop,
“Vpgm_2step_start_even” represents the program level of a program pulse to be applied to cells of even program states, an even number being defined as 2j, during the 1^{st} program loop,
“Vpgm_1step_stored_j^{th}” represents the j^{th} program level,
“offset_even” represents an offset voltage level for the even program states at the 1^{st} program loop,
“Vpgm_2step_start_odd” represents the program level of a program pulse to be applied to cells of odd program states, an odd number being defined as 2j+1, during the 1^{st} program loop, and
“offset_odd” represents an offset voltage level for the odd program states at the 1^{st} program loop.

The T^{th} step program process may include determining, during the series of consecutive program pulse application operations within a 1^{st} one of the plural program loops, a program level of each of the series of consecutive program pulses based on the J number of stored program levels according to a following equation group 2:

$$Vpgm\_ 2 step\_start for P 1 = Vpgm\_ 1 step\_stored \_ {1}^{st} + offset\_ 1 \qquad [ Equation group 2 ]$$

$$Vpgm\_ 2 step\_start \_even ( even = 2 * j - 2 ) for even Ps = Vpgm\_ 1 step\_stored {\_j}^{th} + offset\_even$$

$$Vpgm\_ 2 step\_start \_odd ( odd = 2 * j - 1 ) for odd Ps = Vpgm\_ 1 step\_stored {\_j}^{th} + offset\_odd$$

$$offset\_even \leq offset\_odd ,$$

wherein:
“Vpgm_2step_start for P1” represents the program level of a program pulse to be applied to cells of a first program state during the 1^{st} program loop,
“Vpgm_1step_stored_1^{st}” represents the j^{th} program level with j=1,
“offset_1” represents an offset voltage level for the first program state at the 1^{st} program loop,
“Vpgm_2step_start_even” represents the program level of a program pulse to be applied to cells of even program states, an even number being defined as 2j−2, during the 1^{st} program loop,
“Vpgm_1step_stored_j^{th}” represents the j^{th} program level,
“offset_even” represents an offset voltage level for the even program states at the 1^{st} program loop,
“Vpgm_2step_start_odd” represents the program level of a program pulse to be applied to cells of odd program states, an odd number being defined as 2j−1, during the 1^{st} program loop, and
“offset_odd” represents an offset voltage level for the odd program states at the 1^{st} program loop.

The T^{th} step program process may include determining, during the series of consecutive program pulse application operations within a 1^{st} one of the plural program loops, a program level of each of the series of consecutive program pulses based on the J number of stored program levels according to a following equation group 3:

$$Vpgm\_ 2 step\_start {i}^{th} = Vpgm\_ 1 step\_stored {\_j}^{th} + offset \qquad [ Equation group 3 ]$$

$$i = j ,$$

wherein:
“Vpgm_2step_start_i^{th}” represents the program level of a program pulse to be applied to cells of an i^{th} program state during the 1^{st} program loop,
“Vpgm_1step_stored_j^{th}” represents the j^{th} program level, and
“offset” represents an offset voltage level for all program states at the 1^{st} program loop.

The T^{th} step program process may include determining, during the series of consecutive program pulse application operations within a 1^{st} one of the plural program loops, a program level of each of the series of consecutive program pulses based on the J number of stored program levels according to a following equation group 4:

$$Vpgm\_ 2 step\_start \_even for even Ps = Vpgm\_ 1 step\_stored {\_j}^{th} + offset\_even \qquad [ Equation group 4 ]$$

$$Vpgm\_ 2 step\_start \_odd for odd Ps = Vpgm\_ 1 step\_stored {\_j}^{th} + offset\_odd$$

$$offset\_even \leq offset\_odd ,$$

wherein:
“Vpgm_2step_start_even” represents a program level of a program pulse to be applied to cells of even program states during the 1^{st} program loop,
“Vpgm_1step_stored_j^{th}” represents the j^{th} program level,
“offset_even” represents an offset voltage level for the even program states at the 1^{st} program loop,
“Vpgm_2step_start_odd” represents the program level of a program pulse to be applied to the cells of odd program states during the 1^{st} program loop, and
“offset_odd” represents an offset voltage level for the odd program states at the 1^{st} program loop.

Additional embodiments of the present invention will become apparent from the following description.

### BRIEF DESCRIPTION OF THE DRAWINGS

FIG. 1 is a block diagram illustrating a storage system.

FIG. 2 is a diagram illustrating a structure of a storage device.

FIG. 3 is a diagram illustrating an example of a memory cell array.

FIG. 4 is diagrams illustrating an operation of applying program pulses and verifying pulses in between the program pulses to program cells to corresponding program states.

FIG. 5 is a diagram illustrating a program operation according to a program loop scheme.

FIG. 6 is a diagram illustrating a quick charge loss (QCL) phenomenon.

FIG. 7 is a diagram illustrating a logical operation for determining whether a cell is under the program-permission mode or the program-inhibition mode for a subsequent program pulse application operation according to an embodiment of the present invention.

FIGS. 8 and 9 are tables that a control logic uses to provide page buffers with program data of a corresponding target program level for each of program pulse application operations in the case of a PLC array according to an embodiment of the present invention.

FIG. 10 is a diagram illustrating a first embodiment of the present invention.

FIG. 11 is a diagram illustrating a case that cells of program levels are programmed through a series of consecutive program pulse application operations and then are verified as programmed through a series of consecutive verification operations within a (n−1)^{th} program loop according to an embodiment of the present invention.

FIG. 12 is a diagram illustrating a case that cells of program levels are programmed through a series of consecutive program pulse application operations and then are verified as programmed through a series of consecutive verification operations within a (n−1)^{th} program loop according to an embodiment of the present invention.

FIG. 13 is a diagram illustrating a case that cells of program levels are programmed through a series of consecutive program pulse application operations and then are verified as programmed through a series of consecutive verification operations within a (n−1)^{th} program loop according to an embodiment of the present invention.

FIGS. 14 and 15 are a diagram illustrating a case that cells of program levels are programmed through a series of consecutive program pulse application operations and then are verified as programmed through a series of consecutive verification operations within a (n−1)^{th} program loop according to an embodiment of the present invention.

FIG. 16 is a diagram illustrating a second embodiment of the present invention.

FIG. 17 is a diagram illustrating a case that cells of program levels are programmed through a series of consecutive program pulse application operations and then are verified as programmed through a series of consecutive verification operations within a (n−1)^{th} program loop according to an embodiment of the present invention.

FIG. 18 is a diagram illustrating a case that cells of program levels are programmed through a series of consecutive program pulse application operations and then are verified as programmed through a series of consecutive verification operations within a (n−1)^{th} program loop according to an embodiment of the present invention.

FIG. 19 is a diagram illustrating a case that cells of program levels are programmed through a series of consecutive program pulse application operations and then are verified as programmed through a series of consecutive verification operations within a (n−1)^{th} program loop according to an embodiment of the present invention.

FIGS. 20 and 21 are a diagram illustrating a case that cells of program levels are programmed through a series of consecutive program pulse application operations and then are verified as programmed through a series of consecutive verification operations within a (n−1)^{th} program loop according to an embodiment of the present invention.

FIGS. 22 and 23 are diagrams illustrating a two-step program process as an example of a multi-step program process.

FIG. 24 is a diagram illustrating a two-step program process as an example of a multi-step program process according to an embodiment of the present invention.

FIG. 25 is a diagram illustrating an example where cells are supposed to belong to any of 16 number of states including an erase state and 15 number of program states during a 1^{st} step program process and are supposed to belong to any of 32 number of states including an erase state and 31 number of program states during a 2^{nd} step program process according to an embodiment of the present invention.

FIG. 26 is a diagram illustrating an example where cells are supposed to belong to any of 17 number of states including an erase state and 16 number of program states during a 1^{st} step program process and are supposed to belong to any of 32 number of states including an erase state and 31 number of program states during a 2^{nd} step program process according to an embodiment of the present invention.

FIG. 27 is a diagram illustrating an example where cells are supposed to belong to any of 32 number of states including an erase state and 31 number of program states during a 1^{st} step program process and are supposed to belong to any of 32 number of states including an erase state and 31 number of program states during a 2^{nd} step program process according to an embodiment of the present invention.

FIG. 28 is a diagram illustrating a general example where cells are supposed to belong to any of (X+1) number of states including an erase state and X number of program states during a 1^{st} step program process and are supposed to belong to any of (Y+1) number of states including an erase state and Y number of program states during a 2^{nd} step program process according to an embodiment of the present invention.

### DETAILED DESCRIPTION

Various embodiments of the present invention are described below in more detail with reference to the accompanying drawings. The present invention may, however, be embodied in different forms and thus should not be construed as limited to the embodiments set forth herein. Rather, these embodiments are provided so that this disclosure conveys the scope of the present invention to those skilled in the art. Moreover, reference herein to “an embodiment,” “another embodiment,” or the like is not necessarily to only one embodiment, and different references to any such phrase are not necessarily to the same embodiment(s). The term “embodiments” as used herein does not necessarily refer to all embodiments. Throughout this disclosure, like reference numerals refer to like parts in the figures and embodiments of the present invention.

The present invention can be implemented in numerous ways, including as a process; an apparatus; a system; a computer program product embodied on a computer-readable storage medium; and/or a processor, such as a processor suitable for executing instructions stored on and/or provided by a memory coupled to the processor. In this specification, these implementations, or any other form that the present invention may take, may be referred to as embodiments. In general, the order of the operations of disclosed processes may be altered within the scope of the present invention. Unless stated otherwise, a component such as a processor or a memory described as being suitable for performing a task may be implemented as a general device or circuit component that is configured or otherwise programmed to perform the task at a given time or as a specific device or circuit component that is manufactured to perform the task. As used herein, the term ‘processor’ or the like refers to one or more devices, circuits, and/or processing cores suitable for processing data, such as computer program instructions.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described herein, the code or instructions for implementing the operations of the method embodiments may transform the computer, processor, controller, or other signal processing device into a special-purpose processor for performing methods herein.

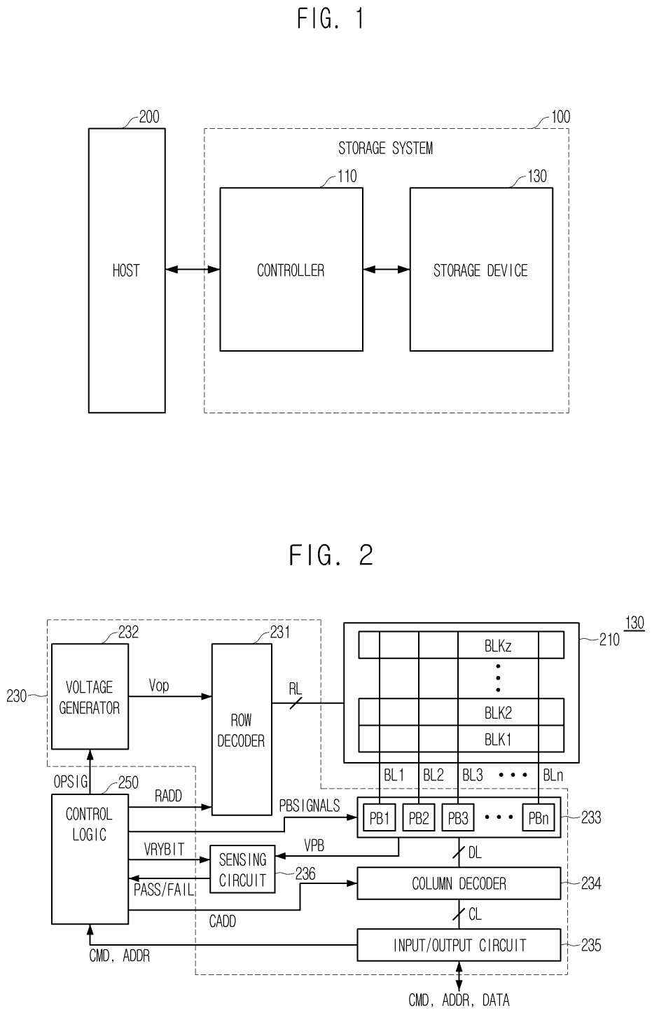

FIG. 1 is a block diagram illustrating a storage system 100.

Referring to FIG. 1, the storage system 100 may include a storage device 130 and a controller 110.

The storage system 100 may access data stored therein in response to a request from a host system 200. Examples of the host system 200 include a cellular phone, a smartphone, an MP3 player, a laptop computer, a desktop computer, a game player, a TV, a tablet PC, and an in-vehicle infotainment system.

The storage system 100 may be implemented as any of various types of storage systems. For example, the storage system 100 may be implemented as a solid state drive (SSD), a multimedia card in the form of a multimedia card (MMC), (e.g., an eMMC, an RS-MMC, or a micro-MMC), a secure digital card in the form of an SD (e.g., a mini-SD or a micro-SD), a universal serial bus (USB) storage device, a universal flash storage (UFS) device, a personal computer memory card international association (PCMCIA) card type storage device, a peripheral component interconnection (PCI) card type storage device, a PCI express (PCI-e) card type storage device, a compact flash (CF) card, a smart media card, or a memory stick.

The storage system 100 may be manufactured through any of various types of packages. For example, the storage system 100 may be manufactured through a package on package (POP), a system in package (SIP), a system on chip (SOC), a multi-chip package (MCP), a chip on board (COB), a wafer-level fabricated package (WFP), or a wafer-level stack package (WSP).

The storage device 130 may access data therein. The storage device 130 may operate in response to a command from the controller 110. The storage device 130 may include a memory cell array 210 including a plurality of memory cells configured to store data therein. The memory cell array may include a plurality of memory blocks. Each of the memory blocks may include pages, each of which includes memory cells. According to an embodiment, data may be stored in and readout from the storage device 130 in units of page-sizes. Data may be erased or removed from the storage device 130 in units of block-sizes.

According to an embodiment, the storage device 130 may be any of Double Data Rate Synchronous Dynamic Random-Access Memory (DDR SDRAM), Low Power Double Data Rate4 (LPDDR4) SDRAM, Graphics Double Data Rate (GDDR) SDRAM, Low Power DDR (LPDDR), Rambus Dynamic Random Access Memory (RDRAM), NAND flash memory, Vertical NAND flash memory, NOR flash memory, resistive random-access memory (RRAM), phase-change random-access memory (PRAM), magneto-resistive random-access memory (MRAM), ferroelectric random-access memory (FRAM), spin-transfer torque random-access memory (STT-RAM) and so forth. By way of example, the storage device 130 can be a NAND flash memory in the context of the following description.

The storage device 130 may have a two-dimensional or three-dimensional array structure. The embodiments of the present invention may be applied not only to a flash memory device, in which a charge storage layer includes a conductive floating gate (FG), but also to a charge trap flash (CTF) memory device, in which a charge storage layer includes an insulating layer.

The storage device 130 may receive a command and an address from the controller 110. The storage device 130 may access, in response to the command, an area selected by the address within the memory cell array. For example, the storage device 130 may perform, in response to the command, various operations such as a write operation or a program operation, a read operation and an erase operation. For example, during the program operation, the storage device 130 may program data into the selected area. During the read operation, the storage device 130 may read data from the selected area. During the erase operation, the storage device 130 may erase or remove data from the selected area.

The controller 110 may control an operation of the storage device 130.

When a power voltage is applied to the storage system 100, the controller 110 may execute firmware such as a Flash Translation Layer (FTL) for controlling communication between the host system 200 and the storage device 130.

According to an embodiment, the controller 110 may receive data and a logical address from the host system 200 and include firmware (not shown) that translates the logical address into a physical address. A logical address may be identified by the host system 200 and may indicate a logical location within the storage device 130. A physical address may indicate an actual location within the storage device 130. The controller 110 may manage, in an operational memory, a logical-to-physical map table representing a mapping relationship between the logical address and the physical address.

In response to a request from the host system 200, the controller 110 may control the storage device 130 to perform an operation. For example, in response to a program request from the host system 200, the controller 110 may provide a program command, a physical address and data to the storage device 130. In response to a read request provided together with a logical address from the host system 200, the controller 110 may provide the storage device 130 with the read command and a physical address corresponding to the logical address. In response to an erase request provided together with a logical address from the host system 200, the controller 110 may provide the storage device 130 with an erase command and a physical address corresponding to the logical address.

Without a request from the host system 200, the controller 110 may control the storage device 130 to perform a background operation such as a program operation for wear leveling or for garbage collection.

According to an embodiment, the storage system 100 may further include an operational memory (not shown). The controller 110 may control data exchange between the host system 200 and the operational memory. The controller 110 may temporarily store, in the operational memory, system data for controlling the storage device 130. For example, the controller 110 may temporarily store, in the operational memory, data from the host system 200 and transfer the temporarily stored data to the storage device 130.

As a buffer memory, the operational memory may store codes or commands executed by the controller 110. As a cache memory, the operational memory may store data processed by the controller 110.

According to an embodiment, the operational memory may be any of DRAM such as DDR SDRAM, LPDDR4 SDRAM, GDDR SDRAM, LPDDR or RDRAM, SRAM and so forth.

The host system 200 may communicate with the storage system 100 through at least one of various communication standards or interfaces such as a Universal Serial Bus (USB), Serial AT Attachment (SATA), a Serial Attached SCSI (SAS), a High Speed Interchip (HSIC), a Small Computer System Interface (SCSI), a Peripheral Component Interconnection (PCI), PCI express (PCIe), NonVolatile Memory express (NVMe), Universal Flash Storage (UFS), Secure Digital (SD), a Multi-Media Card (MMC), an embedded MMC (eMMC), a Dual In-line Memory Module (DIMM), a Registered DIMM (RDIMM), a Load Reduced DIMM (LRDIMM) and so forth.

FIG. 2 is a diagram illustrating a structure of the storage device 130.

Referring to FIG. 2, the storage device 130 may include the memory cell array 210, an operating circuit 230 and a control logic 250.

The memory cell array 210 may include a plurality of memory blocks BLK1 to BLKz coupled to a row decoder 231 through row lines RL, each configured by at least one source select line, a plurality of word lines, and at least one drain select line. The plurality of memory blocks BLK1 to BLKz may be coupled to a page buffer group 233 through bit lines BL1 to BLn. Each of the plurality of memory blocks BLK1 to BLKz may include a plurality of pages. A page may be defined as a group of memory cells coupled to a single word line. The plurality of memory cells may be nonvolatile.

According to an embodiment, the memory cell array 210 may include any of a single-level cell (SLC), a multi-level cell (MLC), a triple-level cell (TLC), a quadruple-level cell (QLC), and a further-higher-level cell, which will not limit the scope of the present disclosure.

The operating circuit 230 may be operable under the control of the control logic 250. The operating circuit 230 may perform an operation on a selected area within the memory cell array 210. The operating circuit 230 may drive the memory cell array 210. For example, the operating circuit 230 may apply various operating voltages to the row lines RL and the bit lines BL1 to BLn or discharge the applied voltages.

The operating circuit 230 may include the row decoder 231, a voltage generator 232, the page buffer group 233, a column decoder 234, an input/output circuit 235 and a sensing circuit 236.

The row decoder 231 may be coupled to the memory cell array 210 through the row lines RL. Within the row lines RL, the word lines may include normal word lines and dummy word lines. The row lines RL may further include a pipe select line.

The row decoder 231 may decode a row address RADD from the control logic 250. The row decoder 231 may select, according to the decoded address, at least one from the memory blocks BLK1 to BLKz. The row decoder 231 may select, according to the decoded address, at least one from the word lines coupled to the selected memory block to apply a voltage Vop from the voltage generator 232 to the selected word line.

For example, during a program pulse process, the row decoder 231 may apply a program voltage to the selected word line and a program pass voltage to unselected word lines. During a verification process, the row decoder 231 may apply a verify voltage to the selected word line and a verify pass voltage to the unselected word lines. During a read operation, the row decoder 231 may apply a read voltage to the selected word line and a read pass voltage to the unselected word lines. During an erase operation, the row decoder 231 may select, according to the decoded address, one of the memory blocks BLK1 to BLKz and may apply a ground voltage to word lines coupled to the selected memory block.

The voltage generator 232 may operate under the control of the control logic 250. The voltage generator 232 may generate various operating voltages Vop through an external power voltage supplied to the storage device 130 or an internal power voltage regulated from the external power voltage. The voltage generator 232 may generate, in response to an operation signal OPSIG, the operating voltages Vop for program, read and erase operations. For example, the voltage generator 232 may generate a program voltage, a verify voltage, a pass voltage, a read voltage, and an erase voltage.

The page buffer group 233 may include first to n-th page buffers PB1 to PBn coupled to the memory cell array 210 through the respective first to n-th bit lines BL1 to BLn. The first to n-th page buffers PB1 to PBn may operate under the control of the control logic 250. The first to n-th page buffers PB1 to PBn may operate in response to page buffer control signals PBSIGNALS. The first to n-th page buffers PB1 to PBn may temporarily store therein data provided through the first to n-th bit lines BL1 to BLn or may sense voltages or currents of the bit lines BL1 to BLn during a read or verification process.

When a program voltage is applied to a selected word line during a program pulse process, the first to n-th page buffers PB1 to PBn may transfer data DATA from the column decoder 234 and the input/output circuit 235 to selected memory cells through the first to n-th bit lines BL1 to BLn. Memory cells of the selected page may be programmed according to the transferred data DATA. During a verification process, the first to n-th page buffers PB1 to PBn may sense a voltage or a current from the first to n-th bit lines BL1 to BLn to read page data from the selected memory cells.

Under the control of the column decoder 234 during a read operation, the first to n-th page buffers PB1 to PBn may read the data DATA from the memory cells of the selected page through the first to n-th bit lines BL1 to BLn and may output the read data DATA to the input/output circuit 235.

During an erase operation, the first to n-th page buffers PB1 to PBn may float the first to n-th bit lines BL1 to BLn or may apply an erase voltage to the first to n-th bit lines BL1 to BLn.

The column decoder 234 may transfer data between the input/output circuit 235 and the page buffer group 233 according to a column address CADD. For example, the column decoder 234 may exchange data with the first to n-th page buffers PB1 to PBn through data lines DL and with the input/output circuit 235 through column lines CL.

The input/output circuit 235 may transfer a command CMD and an address ADDR from the controller 110 to the control logic 250 and may exchange the data DATA with the column decoder 234.

During a read operation or a verification process, the sensing circuit 236 may generate a reference current according to an allowable bit VRYBIT. The sensing circuit 236 may compare a sensing voltage VPB from the page buffer group 233 with a reference voltage generated by the reference current. As the result of the comparison, the sensing circuit 236 may output a pass signal PASS or a fail signal FAIL.

In response to the command CMD and the address ADDR, the control logic 250 may control the operating circuit 230 through the operation signal OPSIG, the row address RADD, the page buffer control signals PBSIGNALS and the allowable bit VRYBIT. The control logic 250 may control a read operation on a selected memory block in response to a sub-block read command and an address. The control logic 250 may control an erase operation on a selected sub-block included in the selected memory block in response to a sub-block erase command and the address. The control logic 250 may determine whether a verification process passes or fails according to the pass or fail signal PASS or FAIL.

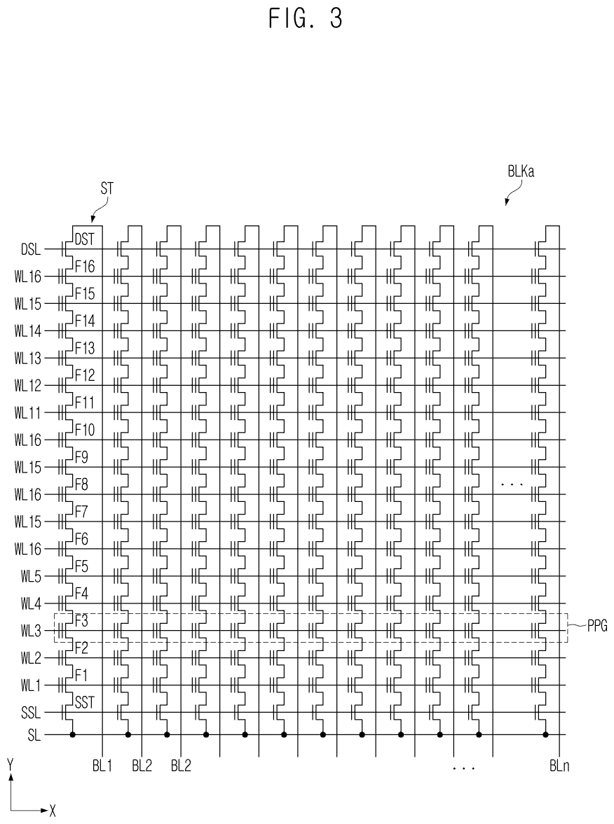

FIG. 3 is a diagram illustrating an example of the memory cell array 210. FIG. 3 is a circuit diagram showing a representative memory block BLKa among the plurality of memory blocks BLK1 to BLKz in the memory cell array 210.

A first select line, word lines, and a second select line arranged in parallel with each other may be coupled to the memory block BLKa. The word lines may be arranged in parallel with each other between the first and second select lines. The first select line may be a source select line SSL and the second select line may be a drain select line DSL.

The memory block BLKa may include a plurality of strings coupled between the bit lines BL1 to BLn and a source line SL. The bit lines BL1 to BLn may be coupled to the respective strings and the strings may be commonly coupled to the source line SL. The strings may have the same configuration and a string ST coupled to the first bit line BL1 is described in detail as an example.

The string ST may include a source select transistor SST, a plurality of memory cells F1 to F16, and a drain select transistor DST coupled in series between the source line SL and the first bit line BL1. Although not illustrated, each string ST may include plural source select transistors SST, plural drain select transistors DST and more than the 16 memory cells F1 to F16.

A source of the source select transistor SST may be coupled to the source line SL and a drain of the drain select transistor DST may be coupled to the first bit line BL1. The memory cells F1 to F16 may be coupled in series between the source select transistor SST and the drain select transistor DST. Gates of the source select transistors SST included in different strings may be coupled to the source select line SSL. Gates of the drain select transistors DST included in the different strings may be coupled to the drain select line DSL. Gates of the memory cells F1 to F16 included in the different strings may be coupled to respective word lines WL1 to WL16. A group of memory cells coupled to the same word line among memory cells included in different strings may be referred to as a physical page PPG. The memory block BLKa may include as many physical pages PPG as the number of word lines WL1 to WL16.

The single physical page PPG including SLCs may store data of a single logical page LPG. The data of the single logical page LPG may include as many bits of data as the number of memory cells included in the single physical page PPG. The single physical page PPG including MLCs may store data of two or more logical pages LPG.

According to an embodiment, a memory block may have a three-dimensional structure. Each memory block may include a plurality of memory cells stacked over a substrate. The plurality of memory cells may be arranged in a +X direction, a +Y direction, and a +Z direction.

In an embodiment, the combination of the operating circuit 230 and the control logic 250 may be referred to as a control circuit. The control circuit may perform an operation on the memory cell array 210 as described herein. The control circuit may perform an operation on the memory cell array 210, as discussed herein.

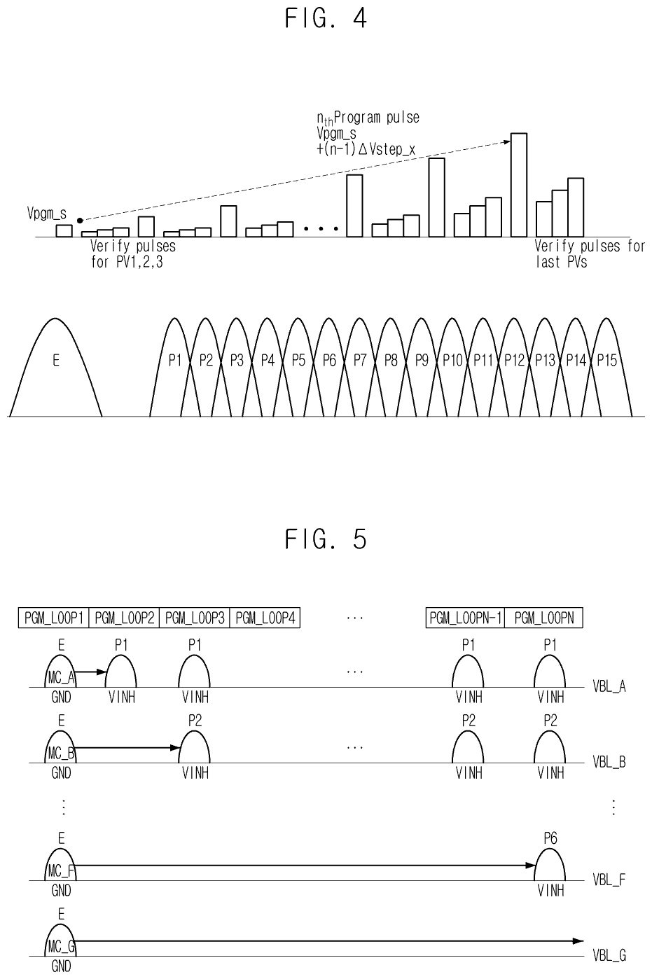

FIG. 4 is diagrams illustrating an operation of applying program pulses and verifying pulses in between the program pulses to program cells to corresponding program states.

Referring to FIG. 4, program data are loaded into the first to n-th page buffers PB1 to PBn connected to the bit-lines of the memory cell array 210. A single program pulse application operation of applying a single program pulse to all cells except for the erased cells. A verification operation immediately follows the single program pulse application operation. If the cell passes a corresponding verify level, the cell is under the program-inhibition mode. By repeating the alternation of the program pulse application operation and the verification operation, all cells become programmed to corresponding program states or corresponding program levels.

FIG. 5 is a diagram illustrating a program operation according to a program loop scheme.

Referring to FIG. 5, a plurality of program loops PGM_LOOP1 to PGM_LOOPN, where N is any suitable number of 2 or more, are performed on selected memory cells during a program operation. A single program operation on a page may comprise the ‘N’ number of program loops PGM_LOOP1 to PGM_LOOPN at maximum. Each of the plurality of program loops PGM_LOOP1 to PGM_LOOPN may include the program pulse process and the verification process. The verification process may be performed according to the pre-verify voltage level Vpre and the main verify voltage level Vmain.

In FIG. 5, by way of example, memory cells are TLCs and programmed from the erase state E to one of first to seventh program states P1 to P7.

As an example, among the selected memory cells to which the program operation is performed, memory cells MC_A may be programmed to the first program state P1, memory cells MC_B to the second program state P2, memory cells MC_C to the third program state P3, memory cells MC_D to the fourth program state P4, memory cells MC_E to the fifth program state P5, memory cells MC_F to the sixth program state P6 and memory cells MC_G to the seventh program state P7. When the program operation is permitted, a voltage of a bit line coupled to each of memory cells MC_A to MC_F may be set to the ground voltage GND or a VM voltage, which is 1V as an example.

In FIG. 5, all memory cells MC_A are programmed to the first program state P1 in the first program loop PGM_LOOP1. Accordingly, a program operation on the memory cells MC_A may be inhibited from the second program loop PGM_LOOP2. Accordingly, from the second program loop PGM_LOOP2, a voltage level of a bit line VBL_A coupled to each of the memory cells MC_A may be set to the program inhibition voltage level VINH.

In FIG. 5, all memory cells MC_B are programmed to the second program state P2 in the second program loop PGM_LOOP2. Accordingly, a program operation on the memory cells MC_B may be inhibited from the third program loop PGM_LOOP3. Accordingly, from the third program loop PGM_LOOP3, a voltage level of a bit line VBL_B coupled to each of the memory cells MC_B may be set to the program inhibition voltage level VINH.

In FIG. 5, all memory cells MC_F are programmed to the sixth program state P6 in the (N−1)^{th} program loop PGM_LOOPN−1. Accordingly, a program operation on the memory cells MC_F may be inhibited from the N^{th} program loop PGM_LOOPN. Accordingly, from the N^{th} program loop PGM_LOOPN, a voltage level of a bit line VBL_F coupled to each of the memory cells MC_F may be set to the program inhibition voltage level VINH. When all memory cells MC_G are programmed to the seventh program state P7 in the N^{th} program loop PGM_LOOPN, all memory cells MC_A to MC_F may be regarded as properly programmed and thus the program operation may then end.

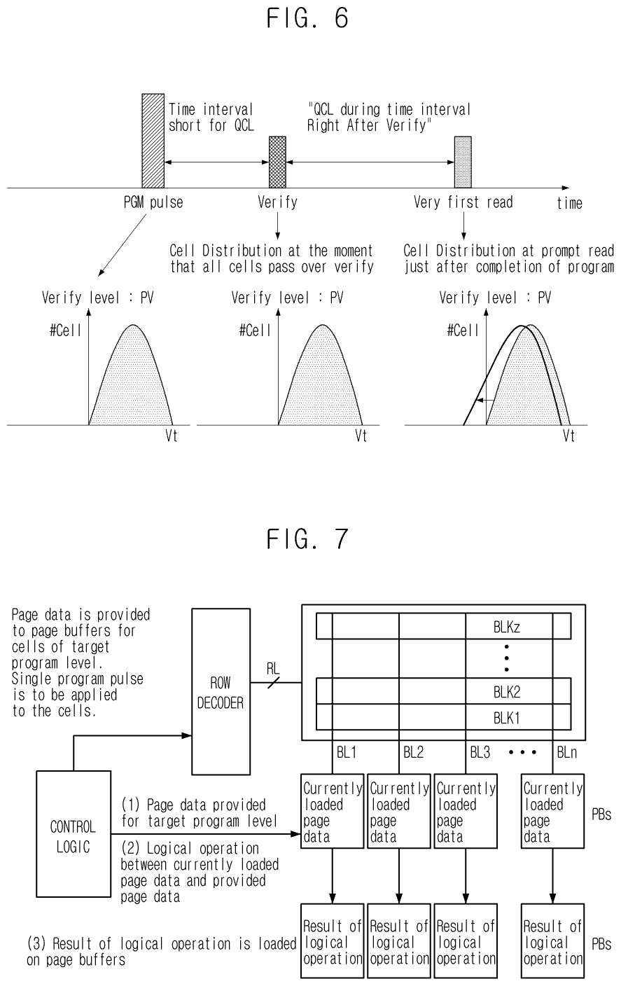

FIG. 6 is a diagram illustrating the quick charge loss (QCL) phenomenon.

The QCL is a phenomenon with a memory cell. Injected charges can either redistribute or escape back in a short time so that the memory cell will exhibit a drop of the threshold voltage thereof in a short time, typically 10 ms time scale. This QCL issue becomes a greater concern as a 3D NAND device keeps scaling and especially when tight threshold voltage distributions are required for, for example, a quadruple-level cell (QLC), a penta-level cell (PLC) or a greater-bit-per-cell.

The QCL occurs after a conventional program loop, i.e., both the program pulse application operation and the verification operation in a storage device 130. The verification operation is not able to identify Vt drop due to QCL because the Vt drop due to QCL happens after a certain time delay longer than the time gap between the program pulse application operation and the verification operation.

For example, a PLC can belong to any of 32 states including one (1) number of erase state and 31 number of program states. Conventional procedure of program in a storage device 130 comprises a program pulse application operation followed by a verification operation. The time gap between the program pulse application operation and the verification operation of applying a verification pulse is not long enough to identify Vt drop due to the QCL. Therefore, even though bits pass over the program verify level by the verification operation, the cell Vt drops due to QCL results in no chance to program the cell again because the verification operation has been completed with a result of the pass.

As a result, the program cell distribution becomes wider, which causes a read failure at a read operation after the program loop. Such QCL phenomenon presents a technical challenge to operate more bits per cell, such as, quadruple-level cell (QLC) and PLC of a storage device 130 requiring an extremely tight cell distribution margin.

A possible solution for the QCL phenomenon is to perform an extra program operation. This extra program operation will push a memory cell with the QCL phenomenon, which drops the threshold voltage thereof, back to the originally intended verify voltage level or higher. However, apparently this extra program operation is at the cost of program time.

An embodiment of the present invention proposes improved program schemes in the storage device 130 to identify the Vt drop due to QCL at the verification operation and to prevent the widening of the cell distribution caused by the QCL.

According to an embodiment of the present invention, a series of consecutive program pulses may be applied to the cells without the intervention of any verification operation in between the application of the series of consecutive program pulses. According to an embodiment of the present invention, a series of consecutive verification pulses may be applied to the cells after the completion of the series of consecutive program pulses.

According to an embodiment of the present invention, the consecutive application of the series of consecutive program pulses and then the consecutive application of the series of consecutive verification pulses configures a single program loop. According to an embodiment of the present invention, the cells may be programmed and verified through one or more program loops. According to an embodiment of the present invention, a program loop comprises a series of consecutive program pulse application operations and then a series of consecutive verification operations. During the series of consecutive program pulse application operations, the series of consecutive program pulse application operations may be performed without the intervention of any verification operation in between the series of consecutive program pulse application operations. After completion of the series of consecutive program pulse application operations, the series of consecutive verification operations may be performed.

During the series of consecutive program pulse application operations, the series of consecutive program pulses may be applied to the cells while updating, according to program data stored in the page buffers PB1 to PBn, an operational mode of each of the cells between the program-permission mode and the program-inhibition mode. A cell under the program-permission mode will be programmed through the application of a program pulse thereto. A cell under the program-inhibition mode will not be programmed despite the application of a program pulse thereto.

During each of the series of consecutive program pulse application operations, a single program pulse may be applied to selected cells of a target program state, which corresponds to a target program level intended through the single program pulse, after the update of program data stored in the page buffers PB1 to PBn. That is, the selected cells of the target program state may be under the program-permission mode for the program pulse application operation. The page buffers PB1 to PBn may be reset for remaining cells other than the selected cells of the target program state and those remaining cells may be under the program-inhibit mode for the program pulse application operation.

It is a logical operation performed in between current and subsequent ones among the series of consecutive program pulse application operations that determines whether a cell is under the program-permission mode or the program-inhibition mode for the subsequent program pulse application operation. The logical operation may be performed on reference data of a target program level for the subsequent program pulse application operation and current program data currently staying loaded on each of the page buffers PB1 to PBn for the current program pulse application operation. The reference data may represent program data of the target program level corresponding to a program pulse to be applied during the subsequent program pulse application operation. The current program data is one currently staying loaded onto the page buffer for the current program pulse application operation. The result of the logical operation may be reflected onto each of the page buffers PB1 to PBn for the subsequent program pulse application operation. The reflection may become the program data staying loaded onto each of the page buffers PB1 to PBn for the subsequent program pulse application operation.

FIG. 7 is a diagram schematically illustrating a logical operation for determining whether a cell is under the program-permission mode or the program-inhibition mode for a subsequent program pulse application operation according to an embodiment of the present invention. FIG. 7 schematically shows the storage device 130 for clear description of the logical operation.

In between the current and subsequent program pulse application operations, the control logic 250 may provide the page buffers PB1 to PBn with reference data of a target program level for the subsequent program pulse application operation. The reference data may represent program data of the target program level corresponding to a program pulse to be applied during the subsequent program pulse application operation. The corresponding program pulse may be applied to the cells of a target program state corresponding to the target program level and optionally to the cells of a higher program state than the target program state. In between the current and subsequent program pulse application operations, the control logic 250 may perform the logical operation on the reference data of the target program level and the current program data currently staying loaded on each of the page buffers PB1 to PBn for the current program pulse application operation. The logical operation causes the respective page buffers PB1 to PBn to update the corresponding program data, which determines the respective cells as under the program-permission mode or the program-inhibition mode for the subsequent program pulse application operation. The result of the logical operation may be reflected onto each of the page buffers PB1 to PBn for the subsequent program pulse application operation. The reflection may become the program data staying loaded onto each of the page buffers PB1 to PBn for the subsequent program pulse application operation. Even without any verification operation in between the current and subsequent program pulse application operations, the logical operation determines whether each of the cells is to be under the program-permission mode or the program-inhibition mode for the subsequent program pulse application operation.

For example, at an initial stage before the 1^{st} program pulse application operation among the 1^{st} to N^{th} program pulse application operations, the control logic 250 may provide the page buffers PB1 to PBn with reference data of the target program level PV1 for the 1^{st} program pulse application operation. The control logic 250 may perform the logical operation on the reference data of the target program level PV1 and initial program data currently staying loaded on each of the page buffers PB1 to PBn. During the 1^{st} program pulse application operation, the cells of the target program state corresponding to the target program level PV1 and optionally the cells of higher program states than the target program level PV1 are to become under the program-permission mode as a result of the logical operation. During the 1^{st} program pulse application operation, a single program pulse for the target program level PV1 is to be applied to the cells under the program-permission mode. During the 1^{st} program pulse application operation, the cells of the lower program state than the target program state, i.e., the erase state are to become under the program-inhibition mode as a result of the logical operation. The cells of the lower program state than the target program state and therefore under the program-inhibition mode are not to be programmed during the 1^{st} program pulse application operation. The control logic 250 may control the storage device 130 to perform the 1^{st} program pulse application operation according to the program data of the target program level PV1 updated on the page buffers PB1 to PBn through the logical operation.

In between the 1^{st} and 2^{nd} program pulse application operations among the 1^{st} to N^{th} program pulse application operations, the control logic 250 may provide the page buffers PB1 to PBn with reference data of the target program level PV2 for the 2^{nd} program pulse application operation, during which the cells of the target program state corresponding to the target program level PV2 and optionally the cells of higher program states than the target program state are to be under the program-permission mode according to the logical operation with the reference data of the target program level PV2. During the 2^{nd} program pulse application operation, a single program pulse for the target program level PV2 is to be applied to the cells under the program-permission mode. During the 2^{nd} program pulse application operation, the cells of the lower program state than the target program state, i.e., the erase state and the program state corresponding to the program level PV1 are to become under the program-inhibition mode according to the logical operation with the reference data of the target program level PV2. The cells of the lower program state than the target program state and therefore under the program-inhibition mode are not to be programmed during the 2^{nd} program pulse application operation. The control logic 250 may control the storage device 130 to perform the 2^{nd} program pulse application operation according to the program data of the target program level PV2 updated on the page buffers PB1 to PBn through the logical operation.

Before the last or N^{th} program pulse application operation among the 1^{st} to N^{th} program pulse application operations, the control logic 250 may provide the page buffers PB1 to PBn with reference data of the target program level PVN for the N^{th} program pulse application operation, during which the cells of the target program state corresponding to the target program level PVN are to be under the program-permission mode according to the logical operation with the reference data of the target program level PVN. During the N^{th} program pulse application operation, a single program pulse for the target program level PVN is to be applied to the cells under the program-permission mode. During the N^{th} program pulse application operation, the cells of the lower program state than the target program state, i.e., the erase state and the 1^{st} to (N−1)^{th} program states corresponding to the program levels PV1 to PVN−1 are to become under the program-inhibition mode according to the logical operation with the reference data of the target program level PVN. The cells of the lower program state than the target program state and therefore under the program-inhibition mode are not to be programmed during the N^{th} program pulse application operation. The control logic 250 may control the storage device 130 to perform the N^{th} program pulse application operation according to the program data of the target program level PVN updated on the page buffers PB1 to PBn through the logical operation.

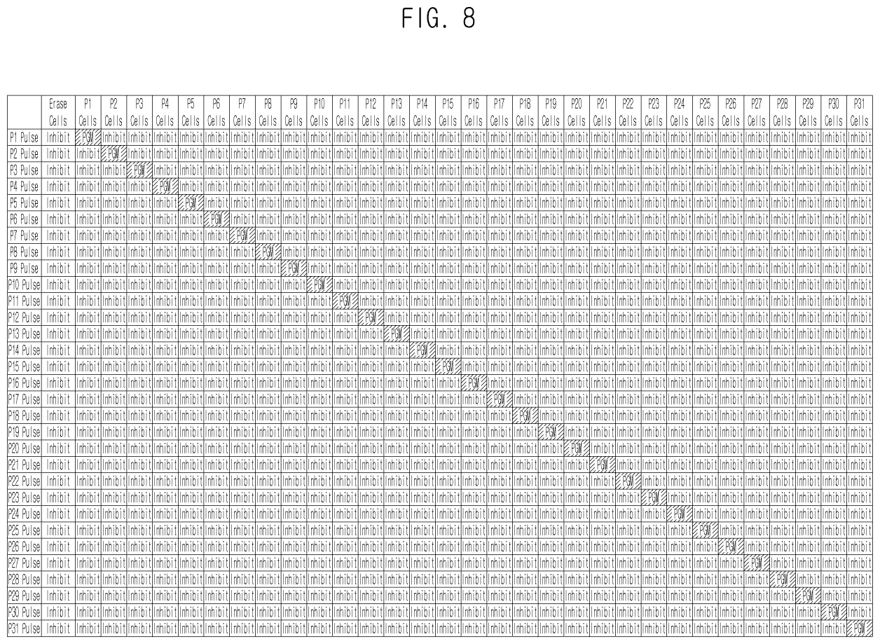

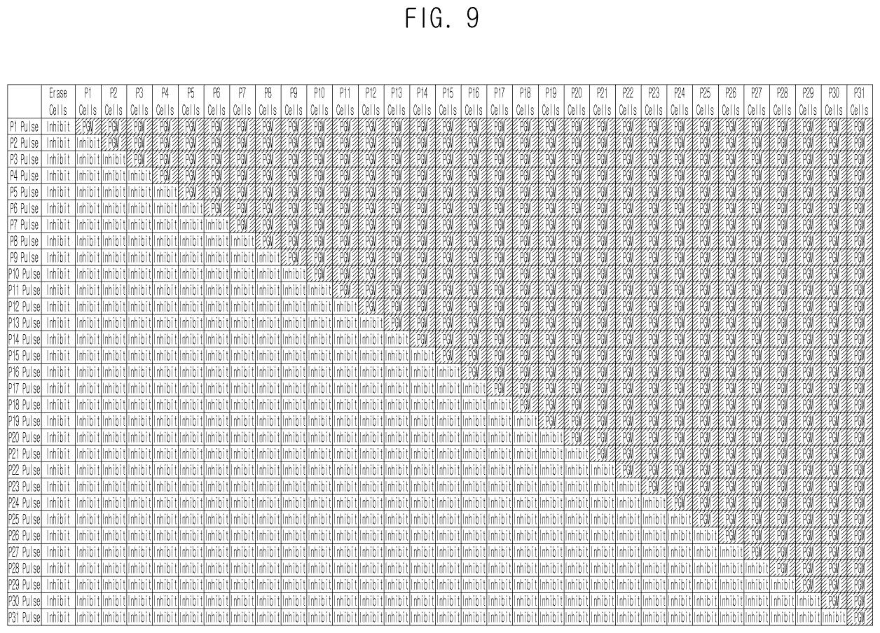

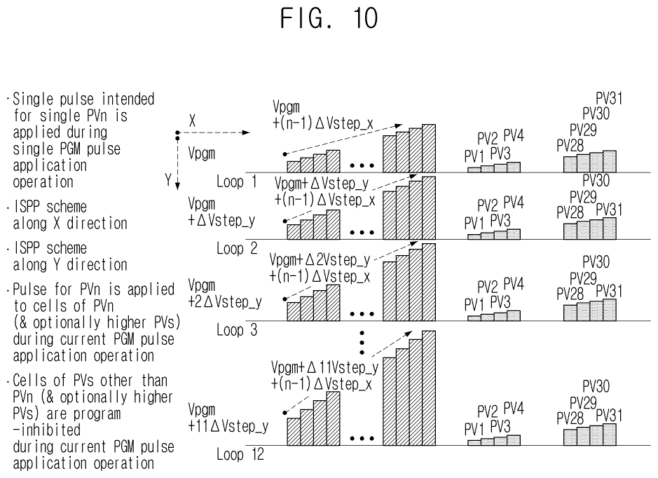

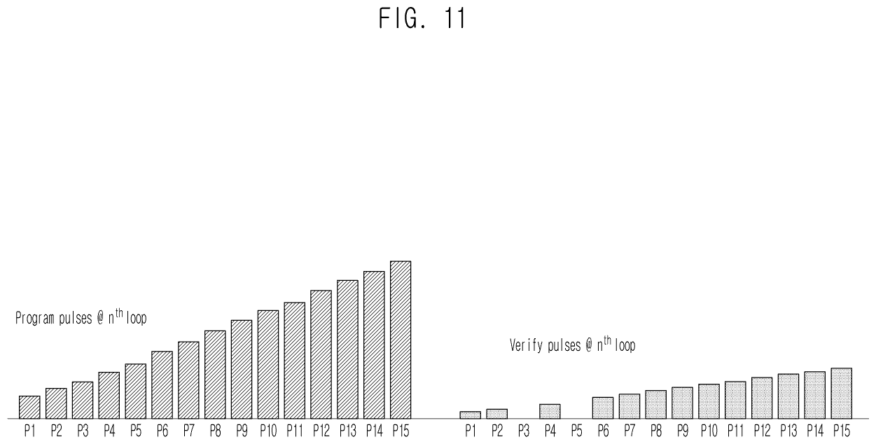

FIGS. 8 and 9 are tables that the control logic 250 uses to provide the page buffers PB1 to PBn with program data of a corresponding target program level for each of the 1^{st} to 31^{st} program pulse application operations in the case of the memory cell array 210 as the PLC array according to an embodiment of the present invention.

Referring to FIGS. 8 and 9, during each program pulse application operation, the PLCs of a corresponding target program state and optionally higher program states are to be under the program-permission mode.

FIG. 8 represents that the PLCs of a corresponding target program state are to be under the program-permission mode during each of the 1^{st} to 31^{st} program pulse application operations.

FIG. 9 represents that the PLCs of a corresponding target program state and higher program states are to be under the program-permission mode during each of the 1^{st} to 31^{st} program pulse application operations.

In the tables of FIGS. 8 and 9, 32 columns represent the PLCs Erase Cells and P1 Cells to P31 Cells of the erase state Erase and 31 number of program states P1 to P31, respectively.

In the tables of FIGS. 8 and 9, 31 rows represent 31 program pulses P1 Pulse to P31 Pulse supposed to be applied to the PLCs during the 31 program pulse application operations for the 31 program levels corresponding to the 31 number of program states P1 to P31, respectively.

In the tables of FIGS. 8 and 9, the highlighted entry “PGM” represents that, during the corresponding program pulse application operation, the corresponding PLC is under the program-permission mode and thus supposed to be programmed through the application of the corresponding program pulse.

In the tables of FIGS. 8 and 9, the non-highlighted entry “inhibit” represents that, during the corresponding program pulse application operation, the corresponding PLC is under the program-inhibition mode and thus supposed not to be programmed despite the application of the corresponding program pulse.

Referring to FIG. 8, as a result of the logical operation on the reference data of the target program level for the subsequent program pulse application operation and the current program data corresponding to a PLC and currently staying loaded on a corresponding one of the page buffers PB1 to PBn for the current program pulse application operation, the PLC may be selected for the to-be-applied program pulse, i.e., the PLC may become under the program-permission mode for the subsequent program pulse application operation when the program level of the current program data is equal to the target program level of the reference data, i.e., when the program level corresponding to the PLC for the current program pulse application operation is equal to the target program level of the reference data.

Referring to FIG. 9, as a result of the logical operation on the reference data of the target program level for the subsequent program pulse application operation and the current program data corresponding to a PLC and currently staying loaded on a corresponding one of the page buffers PB1 to PBn for the current program pulse application operation, the PLC may be selected for the to-be-applied program pulse, i.e., the PLC may become under the program-permission mode for the subsequent program pulse application operation when the program level of the current program data is equal to or higher than the target program level of the reference data, i.e., when the program level corresponding to the PLC for the current program pulse application operation is equal to or higher than the target program level of the reference data.

Referring to FIG. 9, this embodiment accumulates the moderate program pulses for higher program states and thus makes the threshold distribution of the cells narrow before the verification operation, which finally results in narrower threshold distribution of the cells and thus allows larger read margin when compared with a prior art.

In an embodiment, as the series of consecutive program pulse application operations proceed, the levels of the series of consecutive program pulses sequentially step up by an incremental step to program the selected cells from lowest to highest program states. Each of the series of consecutive program pulses may be applied to the selected cells of a corresponding program state and optionally higher program states while program-inhibiting remaining cells other than the selected cells. After the completion of the series of consecutive program pulse application operations for programming the selected cells from lowest to highest program states, the series of consecutive verification operations may be performed for each and every program state.

In an embodiment, as the series of consecutive program pulse application operations proceed, the levels of the series of consecutive program pulses sequentially step down by a decremental step to program the selected cells from highest to lowest program states. Each of the series of consecutive program pulses may be applied to the selected cells of a corresponding program state and optionally higher program states while program-inhibiting remaining cells other than the selected cells. After the completion of the series of consecutive program pulse application operations for programming the selected cells from highest to lowest program states, the series of consecutive verification operations may be performed for each and every program state.

After the completion of the series of consecutive program pulse application operations, the series of consecutive verification operations may be performed for each and every program state. According to a result of the series of consecutive verification operations, the program data loaded in the page buffer may be updated for the next program loop.

As the series of consecutive verification operations proceed, the levels of the series of consecutive verification pulses sequentially step up by an incremental step to verify the selected cells from lowest to highest program states.

In an embodiment, the arrangement of the series of consecutive program pulses has a reverse order to that of the series of consecutive verification pulses. The highest program pulse for the last or the highest program state may be applied first, and then the program pulses sequentially step down by a decremental step as the series of consecutive program pulse application operations proceeds but the verification pulses may be ordered from the lowest to the highest program states.

According to an embodiment of the present invention, the time gap between the program pulse application operation and the verification operation for a random cell can be set to be considerably longer than the conventional scheme where the program/verification pulses are alternately ordered. As a result, the verification operation can identify the Vt drop due to the QCL and the cell of the Vt drop can be re-programmed in the next program loop.

### FIRST EMBODIMENT

FIG. 10 is a diagram illustrating a first embodiment of the present invention. FIG. 10 shows an example of 12 number of program loops each configured by a series of consecutive program pulse application operations and a series of consecutive verification operations to be performed on the memory cell array 210.

Referring to FIG. 10, as the series of consecutive program pulse application operations proceed, the levels of the series of consecutive program pulses sequentially step up by an incremental step ΔVstep_x to program the selected cells from lowest to highest program states according to the incremental step program pulse (ISPP) scheme. Each of the series of consecutive program pulses may be applied to the selected cells of a corresponding program state and optionally higher program states while program-inhibiting remaining cells other than the selected cells.

Within each of the program loops, the series of consecutive program pulses may be applied along the program levels.

In between current and subsequent ones among the series of consecutive program pulse application operations, whether a cell is under the program-permission mode or the program-inhibition mode for the subsequent program pulse application operation may be set by a logical operation on reference data of a target program level for the subsequent program pulse application operation, the reference data being provided from the control logic 250, and current program data currently staying loaded on each of the page buffers PB1 to PBn for the current program pulse application operation.

Through the logical operation, a cell may be selected for the to-be-applied program pulse, i.e., the cell may become under the program-permission mode for the subsequent program pulse application operation when the program level corresponding to the cell for the current program pulse application operation is equal to or optionally higher than the target program level of the reference data for the subsequent program pulse application operation.

The program data, which is updated on each of the page buffers PB1 to PBn coupled to respective cells according to the result of the logical operation, may determine whether a corresponding cell is to become under the program-permission mode or the program-inhibition mode when applying the to-be-applied program pulse during the subsequent program pulse application operation.

Such update of the program data in the page buffers PB1 to PBn may be performed in between the current and subsequent ones among the series of consecutive program pulse application operations.

During the series of consecutive program pulse application operations within each of the program loops, the series of consecutive program pulses may be applied to the cells while updating, according to program data stored in the page buffers PB1 to PBn, an operational mode of each of the cells between the program-permission mode and the program-inhibition mode.

During each of the series of consecutive program pulse application operations within each of the program loops, a single program pulse may be applied to selected cells of a target program state, which corresponds to a target program level intended through the single program pulse, after the update of program data stored in the page buffers PB1 to PBn. That is, the selected cells of the target program state may be under the program-permission mode for the program pulse application operation. The page buffers PB1 to PBn may be reset for remaining cells other than the selected cells of the target program state and those remaining cells may be under the program-inhibit mode for the program pulse application operation.

It is a logical operation performed in between current and subsequent ones among the series of consecutive program pulse application operations that determines whether a cell is under the program-permission mode or the program-inhibition mode for the subsequent program pulse application operation. The logical operation may be performed on reference data of a target program level for the subsequent program pulse application operation and current program data currently staying loaded on each of the page buffers PB1 to PBn for the current program pulse application operation. The reference data may represent program data of the target program level corresponding to a program pulse to be applied during the subsequent program pulse application operation. The current program data is one currently staying loaded onto the page buffer for the current program pulse application operation. The result of the logical operation may be reflected onto each of the page buffers PB1 to PBn for the subsequent program pulse application operation. The reflection may become the program data staying loaded onto each of the page buffers PB1 to PBn for the subsequent program pulse application operation.

In between the current and subsequent program pulse application operations, the control logic 250 may provide the page buffers PB1 to PBn with reference data of a target program level for the subsequent program pulse application operation. The reference data may represent program data of the target program level corresponding to a program pulse to be applied during the subsequent program pulse application operation. The corresponding program pulse may be applied to the cells of a target program state corresponding to the target program level and optionally to the cells of a higher program state than the target program state. In between the current and subsequent program pulse application operations, the control logic 250 may perform the logical operation on the reference data of the target program level and the current program data currently staying loaded on each of the page buffers PB1 to PBn for the current program pulse application operation. The logical operation causes the respective page buffers PB1 to PBn to update the corresponding program data, which determines the respective cells as under the program-permission mode or the program-inhibition mode for the subsequent program pulse application operation. The result of the logical operation may be reflected onto each of the page buffers PB1 to PBn for the subsequent program pulse application operation. The reflection may become the program data staying loaded onto each of the page buffers PB1 to PBn for the subsequent program pulse application operation. Even without any verification operation in between the current and subsequent program pulse application operations, the logical operation determines whether each of the cells is to be under the program-permission mode or the program-inhibition mode for the subsequent program pulse application operation.

For example, at an initial stage before the 1^{st} program pulse application operation among the 1^{st} to N^{th} program pulse application operations, the control logic 250 may provide the page buffers PB1 to PBn with reference data of the target program level PV1 for the 1^{st} program pulse application operation. The control logic 250 may perform the logical operation on the reference data of the target program level PV1 and initial program data currently staying loaded on each of the page buffers PB1 to PBn. During the 1^{st} program pulse application operation, the cells of the target program state corresponding to the target program level PV1 and optionally the cells of higher program states than the target program level PV1 are to become under the program-permission mode as a result of the logical operation. During the 1^{st} program pulse application operation, a single program pulse for the target program level PV1 is to be applied to the cells under the program-permission mode. During the 1^{st} program pulse application operation, the cells of the lower program state than the target program state, i.e., the erase state are to become under the program-inhibition mode as a result of the logical operation. The cells of the lower program state than the target program state and therefore under the program-inhibition mode are not to be programmed during the 1^{st} program pulse application operation. The control logic 250 may control the storage device 130 to perform the 1^{st} program pulse application operation according to the program data of the target program level PV1 updated on the page buffers PB1 to PBn through the logical operation.

In between the 1^{st} and 2^{nd} program pulse application operations among the 1^{st} to N^{th} program pulse application operations, the control logic 250 may provide the page buffers PB1 to PBn with reference data of the target program level PV2 for the 2^{nd} program pulse application operation, during which the cells of the target program state corresponding to the target program level PV2 and optionally the cells of higher program states than the target program state are to be under the program-permission mode according to the logical operation with the reference data of the target program level PV2. During the 2^{nd} program pulse application operation, a single program pulse for the target program level PV2 is to be applied to the cells under the program-permission mode. During the 2^{nd} program pulse application operation, the cells of the lower program state than the target program state, i.e., the erase state and the program state corresponding to the program level PV1 are to become under the program-inhibition mode according to the logical operation with the reference data of the target program level PV2. The cells of the lower program state than the target program state and therefore under the program-inhibition mode are not to be programmed during the 2^{nd} program pulse application operation. The control logic 250 may control the storage device 130 to perform the 2^{nd} program pulse application operation according to the program data of the target program level PV2 updated on the page buffers PB1 to PBn through the logical operation.

Before the last or N^{th} program pulse application operation among the 1^{st} to N^{th} program pulse application operations, the control logic 250 may provide the page buffers PB1 to PBn with reference data of the target program level PVN for the N^{th} program pulse application operation, during which the cells of the target program state corresponding to the target program level PVN are to be under the program-permission mode according to the logical operation with the reference data of the target program level PVN. During the N^{th} program pulse application operation, a single program pulse for the target program level PVN is to be applied to the cells under the program-permission mode. During the N^{th} program pulse application operation, the cells of the lower program state than the target program state, i.e., the erase state and the 1^{st} to (N−1)^{th} program states corresponding to the program levels PV1 to PVN−1 are to become under the program-inhibition mode according to the logical operation with the reference data of the target program level PVN. The cells of the lower program state than the target program state and therefore under the program-inhibition mode are not to be programmed during the N^{th} program pulse application operation. The control logic 250 may control the storage device 130 to perform the N^{th} program pulse application operation according to the program data of the target program level PVN updated on the page buffers PB1 to PBn through the logical operation.

Referring to the table of FIG. 8, during each of the series of consecutive program pulse application operations, one selected program pulse may be applied to the cells of a selected one among the plural program states while program-inhibiting all other cells of all other ones among the plural program states. As a result of the logical operation on the reference data of the target program level for the subsequent program pulse application operation and the current program data corresponding to a PLC and currently staying loaded on a corresponding one of the page buffers PB1 to PBn for the current program pulse application operation, the PLC may be selected for the to-be-applied program pulse, i.e., the PLC may become under the program-permission mode for the subsequent program pulse application operation when the program level of the current program data is equal to the target program level of the reference data, i.e., when the program level corresponding to the PLC for the current program pulse application operation is equal to the target program level of the reference data.

Referring to the table of FIG. 9, during each of the series of consecutive program pulse application operations, one selected program pulse may be applied to the cells of a selected one and higher ones among the plural program states while program-inhibiting all other cells of all other ones lower than the selected program state among the plural program states. As a result of the logical operation on the reference data of the target program level for the subsequent program pulse application operation and the current program data corresponding to a PLC and currently staying loaded on a corresponding one of the page buffers PB1 to PBn for the current program pulse application operation, the PLC may be selected for the to-be-applied program pulse, i.e., the PLC may become under the program-permission mode for the subsequent program pulse application operation when the program level of the current program data is equal to or higher than the target program level of the reference data, i.e., when the program level corresponding to the PLC for the current program pulse application operation is equal to or higher than the target program level of the reference data.

After the completion of the series of consecutive program pulse application operations, the series of consecutive verification operations may be performed for each and every program state. According to a result of the series of consecutive verification operations, the program data loaded in the page buffer may be updated for the next program loop.

Referring to FIG. 10, the arrangement of the series of consecutive program pulses has the forward order to that of the series of consecutive verification pulses. As the series of consecutive verification operations proceed, the levels of the series of consecutive verification pulses sequentially step up by an incremental step ΔVstep_y to verify the selected cells from lowest to highest program states according to the ISPP scheme.

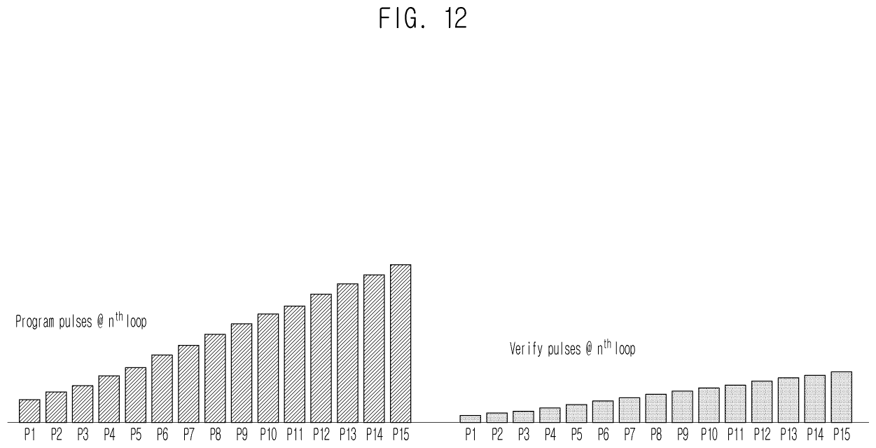

Each of following FIGS. 11 to 15 illustrates an example of one of plural program loops, each comprising a series of consecutive program pulse application operations and a series of consecutive verification operations performed on a QLC array according to an embodiment of the present invention. A QLC may belong to any of an erase state and 15 program states P1 to P15.

According to an embodiment, during each of the series of consecutive program pulse application operations, one selected program pulse may be applied to the cells of a selected one and optionally higher ones among the plural program states while program-inhibiting all other cells of all other ones among the plural program states.

According to an embodiment, a program pulse may be still applied to the cells of a certain program level during a subsequent program loop even when the cells of the certain program level are verified as programmed during a current program loop. However, the cells of the certain program level verified as programmed during the current program loop may become under the program-inhibition mode during a subsequent program loop.

According to an embodiment, a program pulse may not be applied any further to the cells of a certain program level during a subsequent program loop when the cells of the certain program level are verified as programmed during a current program loop.

According to an embodiment, a verification operation may not be performed any further for a certain program level during a subsequent program loop when the cells of the certain program level are verified as programmed during a current program loop.

According to an embodiment, a verification operation may be still performed for a certain program level during a subsequent program loop even when the cells of the certain program level are verified as programmed during a current program loop. There may be a case that the cell of the certain program level may be verified as under-programmed by the verification operation during the subsequent program loop. That is, due to the QCL, there may be the case that the cell of the certain program level is verified as under-programmed during the subsequent program loop even when the cells of the certain program level are previously verified as programmed during the current program loop. In this case, the program pulse may be applied again to the cells of the certain program level during a further subsequent program loop.

FIG. 11 is a diagram illustrating a case that the cells of program levels PV3 and PV5 are programmed through the series of as programmed through the series of consecutive verification operations within a (n−1)^{th} program loop according to an embodiment of the present invention. Within a single program loop, the series of consecutive program pulse application operations and the series of consecutive verification operations may be performed for the program levels corresponding to the program states P1 to P15. FIG. 11 shows a n^{th} program loop subsequent to the (n−1)^{th} program loop.

During the n^{th} program loop, the program pulses for the respective program states P3 and P5, which correspond to the program levels PV3 and PV5, may be applied to the cells of the program states P3 and P5, which are under the program-inhibition mode. That is, during the n^{th} program loop and subsequent program loops, the cells of the program states P3 and P5 may be supposed not to be programmed any further although the program pulses for the respective program states P3 and P5 are applied to the cells of the program states P3 and P5.

During the n^{th} program loop, verification operations may not be performed any further for the program levels PV3 and PV5 corresponding to the respective program states P3 and P5 when the cells of the program states P3 and P5 are verified as programmed during the (n−1)^{th} program loop.

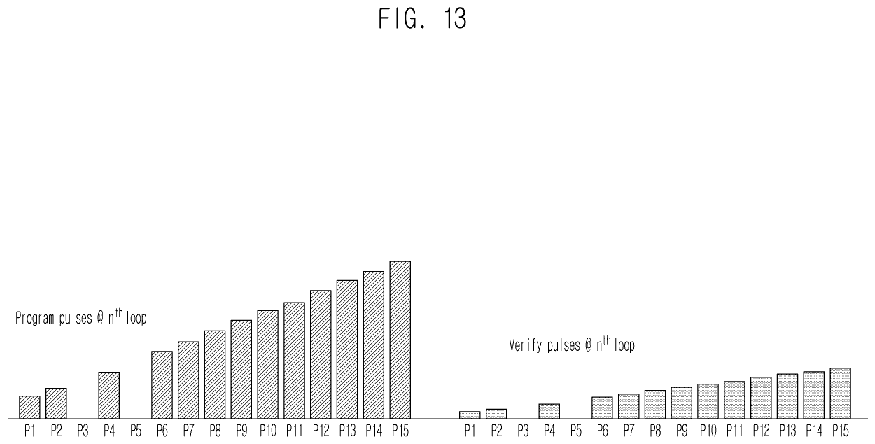

FIG. 12 is a diagram illustrating a case that the cells of program levels PV3 and PV5 are programmed through the series of as programmed through the series of consecutive verification operations within a (n−1)^{th} program loop according to an embodiment of the present invention. Within a single program loop, the series of consecutive program pulse application operations and the series of consecutive verification operations may be performed for the program levels corresponding to the program states P1 to P15. FIG. 12 shows a n^{th} program loop subsequent to the (n−1)^{th} program loop.

During the n^{th} program loop, the program pulses for the respective program states P3 and P5, which correspond to the program levels PV3 and PV5, may be applied to the cells of the program states P3 and P5, which are under the program-inhibition mode. That is, during the n^{th} program loop and subsequent program loops, the cells of the program states P3 and P5 may be supposed not to be programmed any further although the program pulses for the respective program states P3 and P5 are applied to the cells of the program states P3 and P5.

During the n^{th} program loop, verification operations may be still performed for the program levels PV3 and PV5 corresponding to the respective program states P3 and P5 even when the cells of the program states P3 and P5 are verified as programmed during the (n−1)^{th} program loop.

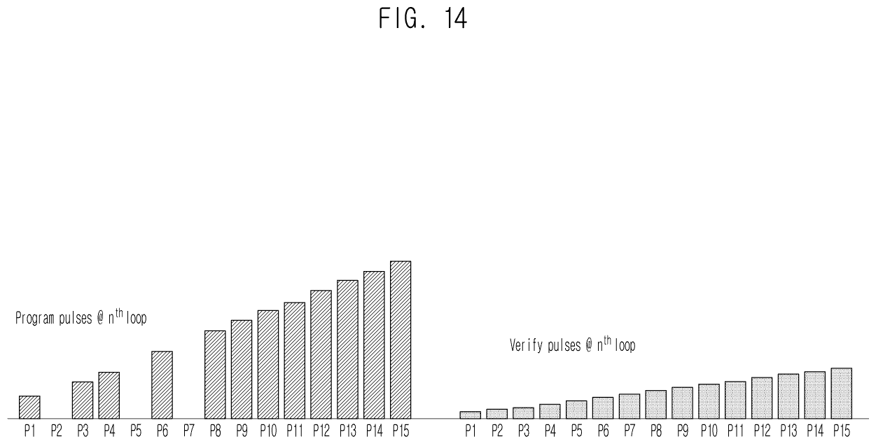

FIG. 13 is a diagram illustrating a case that the cells of program levels PV3 and PV5 are programmed through the series of as programmed through the series of consecutive verification operations within a (n−1)^{th} program loop according to an embodiment of the present invention. Within a single program loop, the series of consecutive program pulse application operations and the series of consecutive verification operations may be performed for the program levels corresponding to the program states P1 to P15. FIG. 13 shows a n^{th} program loop subsequent to the (n−1)^{th} program loop.

During the n^{th} program loop, the program pulses for the respective program states P3 and P5, which correspond to the program levels PV3 and PV5, may not be applied any further to the cells of the program states P3 and P5. That is, during the n^{th} program loop and subsequent program loops, the cells of the program states P3 and P5 may be supposed not to be programmed any further since the program pulses for the respective program states P3 and P5 are not applied any further to the cells of the program states P3 and P5.

During the n^{th} program loop, verification operations may not be performed any further for the program levels PV3 and PV5 corresponding to the respective program states P3 and P5 when the cells of the program states P3 and P5 are verified as programmed during the (n−1)^{th} program loop.

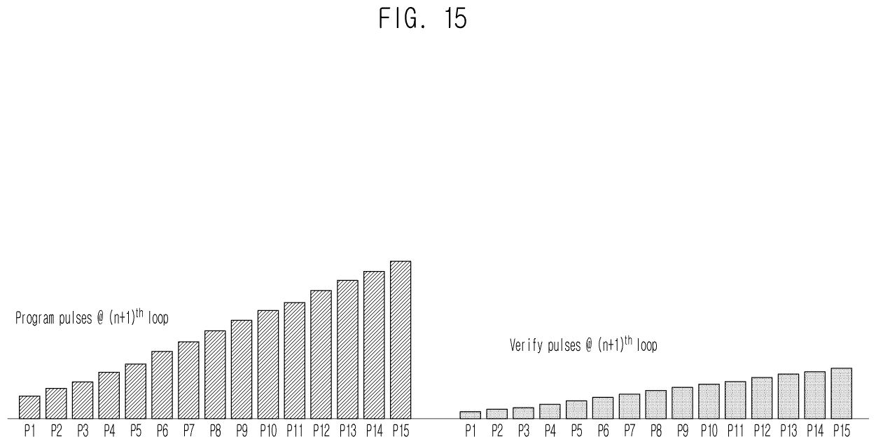

FIGS. 14 and 15 are a diagram illustrating a case that the cells of program levels PV3 and PV5 are programmed through the series of consecutive program pulse application operations and then are verified as programmed through the series of consecutive verification operations within a (n−1)^{th} program loop according to an embodiment of the present invention. Within a single program loop, the series of consecutive program pulse application operations and the series of consecutive verification operations may be performed for the program levels corresponding to the program states P1 to P15. FIGS. 14 and 15 show n^{th} and (n+1)^{th} program loops subsequent to the (n−1)^{th} program loop.

During the n^{th} program loop, the program pulses for the respective program states P3 and P5, which correspond to the program levels PV3 and PV5, may not be applied any further to the cells of the program states P3 and P5. That is, during the n^{th} program loop, the cells of the program states P3 and P5 may be supposed not to be programmed any further since the program pulses for the respective program states P3 and P5 are not applied any further to the cells of the program states P3 and P5.

During the n^{th} program loop, verification operations may be still performed for the program levels PV3 and PV5 corresponding to the respective program states P3 and P5 even when the cells of the program states P3 and P5 are verified as programmed during the (n−1)^{th} program loop.

During the n^{th} program loop, there may be a case that the cell of the program states P3 and P5 may be verified as under-programmed by the verification operation. That is, due to the QCL, there may be the case that the cells of the program states P3 and P5 are verified as under-programmed during the n^{th} program loop even when the cells of the program states P3 and P5 are previously verified as programmed during the (n−1)^{th} program loop.

In this case, the program pulses for the respective program states P3 and P5 may be applied again to the cells of the program states P3 and P5 during the (n+1)^{th} program loop.

### SECOND EMBODIMENT

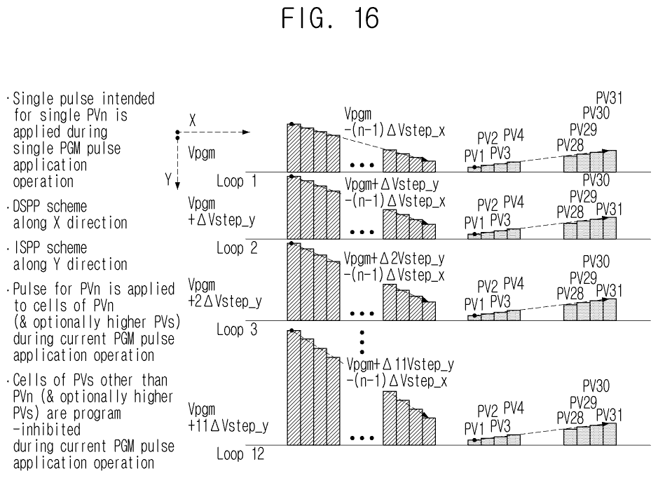

FIG. 16 is a diagram illustrating a second embodiment of the present invention. The following figure shows an example of 12 number of program loops each configured by a series of consecutive program pulse application operations and a series of consecutive verification operations to be performed on a memory cell array 210.

Referring to FIG. 16, as the series of consecutive program pulse application operations proceed, the levels of the series of consecutive program pulses sequentially step down by a decremental step ΔVstep_x to program the selected cells from highest to lowest program states according to the decremental step program pulse (DSPP) scheme. Each of the series of consecutive program pulses may be applied to the selected cells of a corresponding program state and optionally higher program states while program-inhibiting remaining cells other than the selected cells.

Within each of the program loops, the series of consecutive program pulses may be applied along the program levels.

In between current and subsequent ones among the series of consecutive program pulse application operations, whether a cell is under the program-permission mode or the program-inhibition mode for the subsequent program pulse application operation may be set by a logical operation on reference data of a target program level for the subsequent program pulse application operation, the reference data being provided from the control logic 250, and current program data currently staying loaded on each of the page buffers PB1 to PBn for the current program pulse application operation.

Through the logical operation, a cell may be selected for the to-be-applied program pulse, i.e., the cell may become under the program-permission mode for the subsequent program pulse application operation when the program level corresponding to the cell for the current program pulse application operation is equal to or optionally higher than the target program level of the reference data for the subsequent program pulse application operation.

The program data, which is updated on each of the page buffers PB1 to PBn coupled to respective cells according to the result of the logical operation, may determine whether a corresponding cell is to become under the program-permission mode or the program-inhibition mode when applying the to-be-applied program pulse during the subsequent program pulse application operation.

Such update of the program data in the page buffers PB1 to PBn may be performed in between the current and subsequent ones among the series of consecutive program pulse application operations.

During the series of consecutive program pulse application operations within each of the program loops, the series of consecutive program pulses may be applied to the cells while updating, according to program data stored in the page buffers PB1 to PBn, an operational mode of each of the cells between the program-permission mode and the program-inhibition mode.

During each of the series of consecutive program pulse application operations within each of the program loops, a single program pulse may be applied to selected cells of a target program state, which corresponds to a target program level intended through the single program pulse, after the update of program data stored in the page buffers PB1 to PBn. That is, the selected cells of the target program state may be under the program-permission mode for the program pulse application operation. The page buffers PB1 to PBn may be reset for remaining cells other than the selected cells of the target program state and those remaining cells may be under the program-inhibit mode for the program pulse application operation.

It is a logical operation performed in between current and subsequent ones among the series of consecutive program pulse application operations that determines whether a cell is under the program-permission mode or the program-inhibition mode for the subsequent program pulse application operation. The logical operation may be performed on reference data of a target program level for the subsequent program pulse application operation and current program data currently staying loaded on each of the page buffers PB1 to PBn for the current program pulse application operation. The reference data may represent program data of the target program level corresponding to a program pulse to be applied during the subsequent program pulse application operation. The current program data is one currently staying loaded onto the page buffer for the current program pulse application operation. The result of the logical operation may be reflected onto each of the page buffers PB1 to PBn for the subsequent program pulse application operation. The reflection may become the program data staying loaded onto each of the page buffers PB1 to PBn for the subsequent program pulse application operation.

In between the current and subsequent program pulse application operations, the control logic 250 may provide the page buffers PB1 to PBn with reference data of a target program level for the subsequent program pulse application operation. The reference data may represent program data of the target program level corresponding to a program pulse to be applied during the subsequent program pulse application operation. The corresponding program pulse may be applied to the cells of a target program state corresponding to the target program level and optionally to the cells of a higher program state than the target program state. In between the current and subsequent program pulse application operations, the control logic 250 may perform the logical operation on the reference data of the target program level and the current program data currently staying loaded on each of the page buffers PB1 to PBn for the current program pulse application operation. The logical operation causes the respective page buffers PB1 to PBn to update the corresponding program data, which determines the respective cells as under the program-permission mode or the program-inhibition mode for the subsequent program pulse application operation. The result of the logical operation may be reflected onto each of the page buffers PB1 to PBn for the subsequent program pulse application operation. The reflection may become the program data staying loaded onto each of the page buffers PB1 to PBn for the subsequent program pulse application operation. Even without any verification operation in between the current and subsequent program pulse application operations, the logical operation determines whether each of the cells is to be under the program-permission mode or the program-inhibition mode for the subsequent program pulse application operation.

For example, at an initial stage before the 1^{st} program pulse application operation among the 1^{st} to N^{th} program pulse application operations, the control logic 250 may provide the page buffers PB1 to PBn with reference data of the target program level PV1 for the 1^{st} program pulse application operation. The control logic 250 may perform the logical operation on the reference data of the target program level PV1 and initial program data currently staying loaded on each of the page buffers PB1 to PBn. During the 1^{st} program pulse application operation, the cells of the target program state corresponding to the target program level PV1 and optionally the cells of higher program states than the target program level PV1 are to become under the program-permission mode as a result of the logical operation. During the 1^{st} program pulse application operation, a single program pulse for the target program level PV1 is to be applied to the cells under the program-permission mode. During the 1^{st} program pulse application operation, the cells of the lower program state than the target program state, i.e., the erase state are to become under the program-inhibition mode as a result of the logical operation. The cells of the lower program state than the target program state and therefore under the program-inhibition mode are not to be programmed during the 1^{st} program pulse application operation. The control logic 250 may control the storage device 130 to perform the 1^{st} program pulse application operation according to the program data of the target program level PV1 updated on the page buffers PB1 to PBn through the logical operation.

In between the 1^{st} and 2^{nd} program pulse application operations among the 1^{st} to N^{th} program pulse application operations, the control logic 250 may provide the page buffers PB1 to PBn with reference data of the target program level PV2 for the 2^{nd} program pulse application operation, during which the cells of the target program state corresponding to the target program level PV2 and optionally the cells of higher program states than the target program state are to be under the program-permission mode according to the logical operation with the reference data of the target program level PV2. During the 2^{nd} program pulse application operation, a single program pulse for the target program level PV2 is to be applied to the cells under the program-permission mode. During the 2^{nd} program pulse application operation, the cells of the lower program state than the target program state, i.e., the erase state and the program state corresponding to the program level PV1 are to become under the program-inhibition mode according to the logical operation with the reference data of the target program level PV2. The cells of the lower program state than the target program state and therefore under the program-inhibition mode are not to be programmed during the 2^{nd} program pulse application operation. The control logic 250 may control the storage device 130 to perform the 2^{nd} program pulse application operation according to the program data of the target program level PV2 updated on the page buffers PB1 to PBn through the logical operation.

Before the last or N^{th} program pulse application operation among the 1^{st} to N^{th} program pulse application operations, the control logic 250 may provide the page buffers PB1 to PBn with reference data of the target program level PVN for the N^{th} program pulse application operation, during which the cells of the target program state corresponding to the target program level PVN are to be under the program-permission mode according to the logical operation with the reference data of the target program level PVN. During the N^{th} program pulse application operation, a single program pulse for the target program level PVN is to be applied to the cells under the program-permission mode. During the N^{th} program pulse application operation, the cells of the lower program state than the target program state, i.e., the erase state and the 1^{st} to (N−1)^{th} program states corresponding to the program levels PV1 to PVN−1 are to become under the program-inhibition mode according to the logical operation with the reference data of the target program level PVN. The cells of the lower program state than the target program state and therefore under the program-inhibition mode are not to be programmed during the N^{th} program pulse application operation. The control logic 250 may control the storage device 130 to perform the N^{th} program pulse application operation according to the program data of the target program level PVN updated on the page buffers PB1 to PBn through the logical operation.

Referring to the table of FIG. 8, during each of the series of consecutive program pulse application operations, one selected program pulse may be applied to the cells of a selected one among the plural program states while program-inhibiting all other cells of all other ones among the plural program states. As a result of the logical operation on the reference data of the target program level for the subsequent program pulse application operation and the current program data corresponding to a PLC and currently staying loaded on a corresponding one of the page buffers PB1 to PBn for the current program pulse application operation, the PLC may be selected for the to-be-applied program pulse, i.e., the PLC may become under the program-permission mode for the subsequent program pulse application operation when the program level of the current program data is equal to the target program level of the reference data, i.e., when the program level corresponding to the PLC for the current program pulse application operation is equal to the target program level of the reference data.

Referring to the table of FIG. 9, during each of the series of consecutive program pulse application operations, one selected program pulse may be applied to the cells of a selected one and higher ones among the plural program states while program-inhibiting all other cells of all other ones lower than the selected program state among the plural program states. As a result of the logical operation on the reference data of the target program level for the subsequent program pulse application operation and the current program data corresponding to a PLC and currently staying loaded on a corresponding one of the page buffers PB1 to PBn for the current program pulse application operation, the PLC may be selected for the to-be-applied program pulse, i.e., the PLC may become under the program-permission mode for the subsequent program pulse application operation when the program level of the current program data is equal to or higher than the target program level of the reference data, i.e., when the program level corresponding to the PLC for the current program pulse application operation is equal to or higher than the target program level of the reference data.

After the completion of the series of consecutive program pulse application operations for programming the selected cells from highest to lowest program states, the series of consecutive verification operations may be performed for each and every program state. According to a result of the series of consecutive verification operations, the program data loaded in the page buffer may be updated for the next program loop.

Referring to FIG. 16, the arrangement of the series of consecutive program pulses has the reverse order to that of the series of consecutive verification pulses. As the series of consecutive verification operations proceed, the levels of the series of consecutive verification pulses sequentially step up by an incremental step ΔVstep_y to verify the selected cells from lowest to highest program states according to the ISPP scheme.

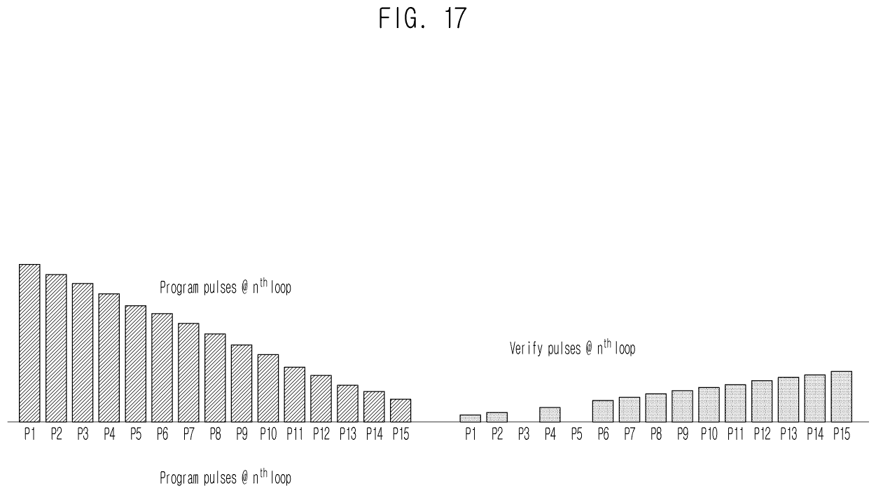

Each of following FIGS. 17 to 21 illustrates an example of one of plural program loops, each comprising a series of consecutive program pulse application operations and a series of consecutive verification operations performed on a QLC array according to embodiments of the present invention. A QLC may belong to any of an erase state and 15 program states P1 to P15.

According to an embodiment, during each of the series of consecutive program pulse application operations, one selected program pulse may be applied to the cells of a selected one and optionally higher ones among the plural program states while program-inhibiting all other cells of all other ones among the plural program states.

According to an embodiment, a program pulse may be still applied to the cells of a certain program level during a subsequent program loop even when the cells of the certain program level are verified as programmed during a current program loop. However, the cells of the certain program level verified as programmed during the current program loop may become under the program-inhibition mode during a subsequent program loop.

According to an embodiment, a program pulse may not be applied any further to the cells of a certain program level during a subsequent program loop when the cells of the certain program level are verified as programmed during a current program loop.

According to an embodiment, a verification operation may not be performed any further for a certain program level during a subsequent program loop when the cells of the certain program level are verified as programmed during a current program loop.

According to an embodiment, a verification operation may be still performed for a certain program level during a subsequent program loop even when the cells of the certain program level are verified as programmed during a current program loop. There may be a case that the cell of the certain program level may be verified as under-programmed by the verification operation during the subsequent program loop. That is, due to the QCL, there may be the case that the cell of the certain program level is verified as under-programmed during the subsequent program loop even when the cells of the certain program level are previously verified as programmed during the current program loop. In this case, the program pulse may be applied again to the cells of the certain program level during a further subsequent program loop.

FIG. 17 is a diagram illustrating a case that the cells of program levels PV3 and PV5 are programmed through the series of consecutive program pulse application operations and then are verified as programmed through the series of consecutive verification operations within a (n−1)^{th} program loop according to embodiments of the present invention. Within a single program loop, the series of consecutive program pulse application operations and the series of consecutive verification operations may be performed for the program levels corresponding to the program states P1 to P15. FIG. 17 shows a n^{th} program loop subsequent to the (n−1)^{th} program loop.

During the n^{th} program loop, the program pulses for the respective program states P3 and P5, which correspond to the program levels PV3 and PV5, may be applied to the cells of the program states P3 and P5, which are under the program-inhibition mode. That is, during the n^{th} program loop and subsequent program loops, the cells of the program states P3 and P5 may be supposed not to be programmed any further although the program pulses for the respective program states P3 and P5 are applied to the cells of the program states P3 and P5.

During the n^{th} program loop, verification operations may not be performed any further for the program levels PV3 and PV5 corresponding to the respective program states P3 and P5 when the cells of the program states P3 and P5 are verified as programmed during the (n−1)^{th} program loop.

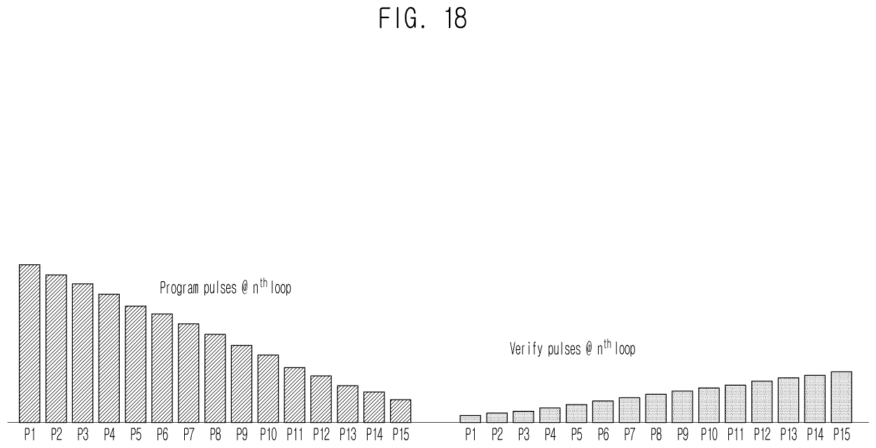

FIG. 18 is a diagram illustrating a case that the cells of program levels PV3 and PV5 are programmed through the series of consecutive program pulse application operations and then are verified as programmed through the series of consecutive verification operations within a (n−1)^{th} program loop according to embodiments of the present invention. Within a single program loop, the series of consecutive program pulse application operations and the series of consecutive verification operations may be performed for the program levels corresponding to the program states P1 to P15. FIG. 18 shows a n^{th} program loop subsequent to the (n−1)^{th} program loop.

During the n^{th} program loop, the program pulses for the respective program states P3 and P5, which correspond to the program levels PV3 and PV5, may be applied to the cells of the program states P3 and P5, which are under the program-inhibition mode. That is, during the n^{th} program loop and subsequent program loops, the cells of the program states P3 and P5 may be supposed not to be programmed any further although the program pulses for the respective program states P3 and P5 are applied to the cells of the program states P3 and P5.

During the n^{th} program loop, verification operations may be still performed for the program levels PV3 and PV5 corresponding to the respective program states P3 and P5 even when the cells of the program states P3 and P5 are verified as programmed during the (n−1)^{th} program loop.

FIG. 19 is a diagram illustrating a case that the cells of program levels PV3 and PV5 are programmed through the series of consecutive program pulse application operations and then are verified as programmed through the series of consecutive verification operations within a (n−1)^{th} program loop according to embodiments of the present invention. Within a single program loop, the series of consecutive program pulse application operations and the series of consecutive verification operations may be performed for the program levels corresponding to the program states P1 to P15. FIG. 19 shows a n^{th} program loop subsequent to the (n−1)^{th} program loop.

During the n^{th} program loop, the program pulses for the respective program states P3 and P5, which correspond to the program levels PV3 and PV5, may not be applied any further to the cells of the program states P3 and P5. That is, during the n^{th} program loop and subsequent program loops, the cells of the program states P3 and P5 may be supposed not to be programmed any further since the program pulses for the respective program states P3 and P5 are not applied any further to the cells of the program states P3 and P5.

During the n^{th} program loop, verification operations may not be performed any further for the program levels PV3 and PV5 corresponding to the respective program states P3 and P5 when the cells of the program states P3 and P5 are verified as programmed during the (n−1)^{th} program loop.

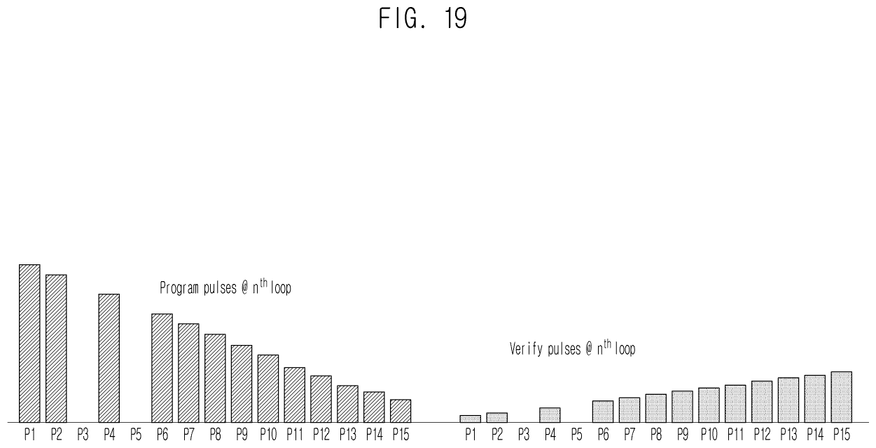

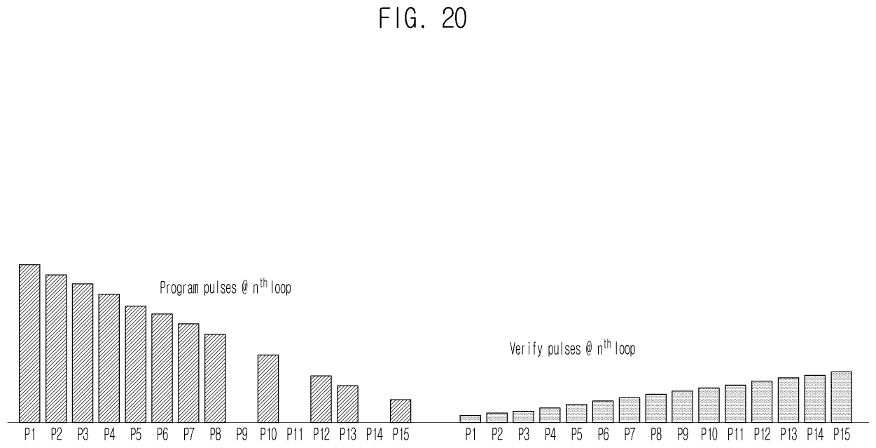

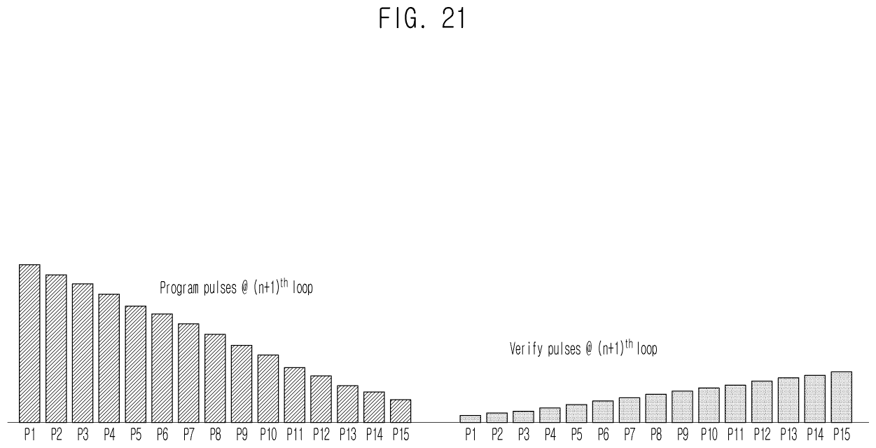

FIGS. 20 and 21 are diagrams illustrating a case that the cells of program levels PV9, PV11 and PV14 are programmed through the series of consecutive program pulse application operations and then are verified as programmed through the series of consecutive verification operations within a (n−1)^{th} program loop according to embodiments of the present invention. Within a single program loop, the series of consecutive program pulse application operations and the series of consecutive verification operations may be performed for the program levels corresponding to the program states P1 to P15. FIGS. 20 and 21 show n^{th} and (n+1)^{th} program loops subsequent to the (n−1)^{th} program loop.

During the n^{th} program loop, the program pulses for the respective program states P9, P11 and P14, which correspond to the program levels PV9, PV11 and PV14, may not be applied any further to the cells of the program states P9, P11 and P14. That is, during the n^{th} program loop, the cells of the program states P9, P11 and P14 may be supposed not to be programmed any further since the program pulses for the respective program states P9, P11 and P14 are not applied any further to the cells of the program states P9, P11 and P14.

During the n^{th} program loop, verification operations may be still performed for the program levels PV9, PV11 and PV14 corresponding to the respective program states P9, P11 and P14 even when the cells of the program states P9, P11 and P14 are verified as programmed during the (n−1)^{th} program loop.

During the n^{th} program loop, there may be a case that the cell of the program states P9, P11 and P14 may be verified as under-programmed by the verification operation. That is, due to the QCL, there may be the case that the cells of the program states P9, P11 and P14 are verified as under-programmed during the n^{th} program loop even when the cells of the program states P9, P11 and P14 are previously verified as programmed during the (n−1)^{th} program loop.

In this case, the program pulses for the respective program states P9, P11 and P14 may be applied again to the cells of the program states P9, P11 and P14 during the (n+1)^{th} program loop.

### Summary of First and Second Embodiments

The following is the summary of at least a part of features of the first and second embodiments.

1. According to the first and second embodiments, the series of consecutive program pulses may be applied along the program levels. In between current and subsequent ones among the series of consecutive program pulse application operations, whether a cell is under the program-permission mode or the program-inhibition mode for the subsequent program pulse application operation may be set by a logical operation on reference data of a target program level for the subsequent program pulse application operation, the reference data being provided from the control logic 250, and current program data currently staying loaded on each of the page buffers PB1 to PBn for the current program pulse application operation. Through the logical operation, a cell may be selected for the to-be-applied program pulse, i.e., the cell may become under the program-permission mode for the subsequent program pulse application operation when the program level corresponding to the cell for the current program pulse application operation is equal to or optionally higher than the target program level of the reference data for the subsequent program pulse application operation. The program data, which is updated on each of the page buffers PB1 to PBn coupled to respective cells according to the result of the logical operation, may determine whether a corresponding cell is to become under the program-permission mode or the program-inhibition mode when applying the to-be-applied program pulse during the subsequent program pulse application operation. Such update of the program data in the page buffers PB1 to PBn may be performed in between the current and subsequent ones among the series of consecutive program pulse application operations.

2. According to the first embodiment, the arrangement of the series of consecutive program pulses has a forward order to that of the series of consecutive verification pulses. As the series of consecutive program pulse application operations proceed, the levels of the series of consecutive program pulses sequentially step up by an incremental step to program the selected cells from lowest to highest program states. Each of the series of consecutive program pulses may be applied to the selected cells of a corresponding program state and optionally higher program states while program-inhibiting remaining cells other than the selected cells. After the completion of the series of consecutive program pulse application operations for programming the selected cells from lowest to highest program states, the series of consecutive verification operations may be performed for each and every program state. As the series of consecutive verification operations proceed, the levels of the series of consecutive verification pulses sequentially step up by an incremental step to verify the selected cells from lowest to highest program states. According to this configuration, the time delay can be set to be longer and thus the Vt shift driven by the stronger QCL on the higher program states can be identified much by the verification operations.

3. According to the first embodiment, during each of the series of consecutive program pulse application operations, one selected program pulse may be applied to the cells of a selected one among the plural program states while program-inhibiting all other cells of all other ones among the plural program states.

4. According to the first embodiment, during each of the series of consecutive program pulse application operations, one selected program pulse may be applied to the cells of a selected one and higher ones among the plural program states while program-inhibiting all other cells of all other ones lower than the selected program state among the plural program states.

5. According to the first embodiment, a program pulse may be still applied to the cells of a certain program level during a subsequent program loop even when the cells of the certain program level are verified as programmed during a current program loop. However, the cells of the certain program level verified as programmed during the current program loop may become under the program-inhibition mode during a subsequent program loop.

6. According to the first embodiment, a program pulse may not be applied any further to the cells of a certain program level during a subsequent program loop when the cells of the certain program level are verified as programmed during a current program loop.

7. According to the first embodiment, a verification operation may not be performed any further for a certain program level during a subsequent program loop when the cells of the certain program level are verified as programmed during a current program loop.

8. According to the first embodiment, a verification operation may be still performed for a certain program level during a current program loop even when the cells of the certain program level are previously verified as programmed and therefore a program pulse may not be applied any further to the cells of the certain program level during a previous program loop, as discussed in the above summary item 6. There may be a case that the cell of the certain program level may be verified as under-programmed by the verification operation during the current program loop. That is, due to the QCL, there may be the case that the cell of the certain program level is verified as under-programmed during the current program loop even when the cells of the certain program level are previously verified as programmed during the previous program loop. In this case, the program pulse may be applied again to the cells of the certain program level during the subsequent program loop.

9. According to the second embodiment, the arrangement of the series of consecutive program pulses has a reverse order to that of the series of consecutive verification pulses. As the series of consecutive program pulse application operations proceed, the levels of the series of consecutive program pulses sequentially step down by a decremental step to program the selected cells from highest to lowest program states. Each of the series of consecutive program pulses may be applied to the selected cells of a corresponding program state and optionally higher program states while program-inhibiting remaining cells other than the selected cells. After the completion of the series of consecutive program pulse application operations for programming the selected cells from highest to lowest program states, the series of consecutive verification operations may be performed for each and every program state. As the series of consecutive verification operations proceed, the levels of the series of consecutive verification pulses sequentially step up by an incremental step to verify the selected cells from lowest to highest program states. According to this configuration, the time delay can be set to be longer than the first embodiment and thus the Vt shift driven by the stronger QCL on the higher program states can be identified much by the verification operations.

10. According to the second embodiment, during each of the series of consecutive program pulse application operations, one selected program pulse may be applied to the cells of a selected one among the plural program states while program-inhibiting all other cells of all other ones among the plural program states.

11. According to the second embodiment, during each of the series of consecutive program pulse application operations, one selected program pulse may be applied to the cells of a selected one and higher ones among the plural program states while program-inhibiting all other cells of all other ones lower than the selected program state among the plural program states.

12. According to the second embodiment, a program pulse may be still applied to the cells of a certain program level during a subsequent program loop even when the cells of the certain program level are verified as programmed during a current program loop. However, the cells of the certain program level verified as programmed during the current program loop may become under the program-inhibition mode during a subsequent program loop.

13. According to the second embodiment, a program pulse may not be applied any further to the cells of a certain program level during a subsequent program loop when the cells of the certain program level are verified as programmed during a current program loop.

14. According to the second embodiment, a verification operation may not be performed any further for a certain program level during a subsequent program loop when the cells of the certain program level are verified as programmed during a current program loop.

15. According to the second embodiment, a verification operation may be still performed for a certain program level during a subsequent program loop even when the cells of the certain program level are verified as programmed during a current program loop. There may be a case that the cell of the certain program level may be verified as under-programmed by the verification operation during the subsequent program loop. That is, due to the QCL, there may be the case that the cell of the certain program level is verified as under-programmed during the subsequent program loop even when the cells of the certain program level are previously verified as programmed during the current program loop. In this case, the program pulse may be applied again to the cells of the certain program level during a further subsequent program loop.

### THIRD EMBODIMENT

Applied to a multi-step program process may be the present invention of programming and verifying the cells of multiple bits per cell such as QLC and PLC through one or more program loops each comprising the series of consecutive program pulse application operations and the series of consecutive verification operations.

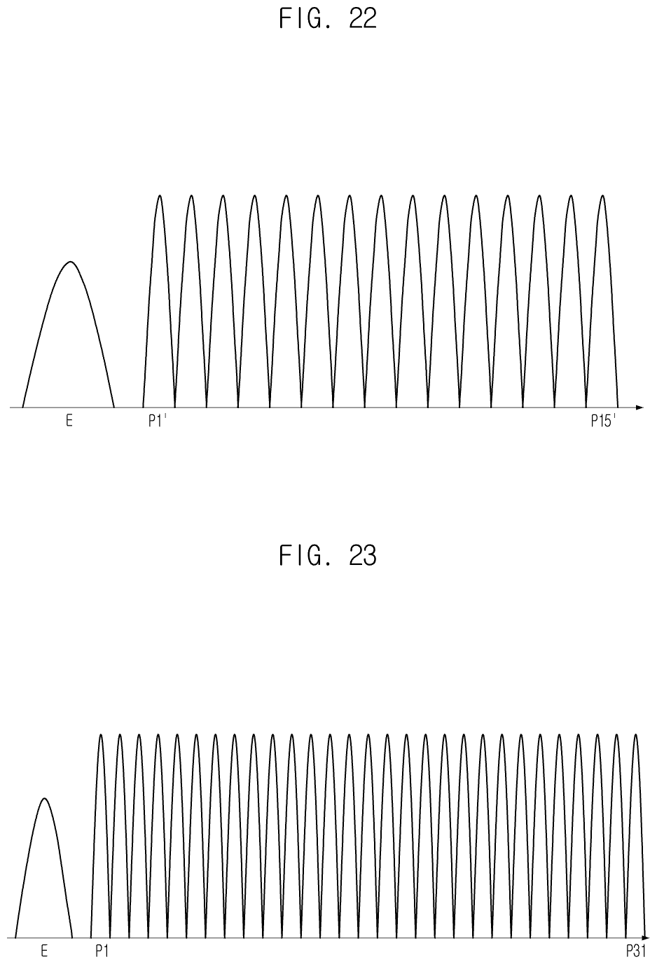

FIGS. 22 and 23 are diagrams illustrating a two-step program process as an example of a multi-step program process.

In the present disclosure, an example is provided using the two-step program process on a PLC page. This example will not limit the scope of the present disclosure. For example, when T-step program process (T is three or greater) as the multi-step program process is applied to the present disclosure instead of the two-step program process, the (T−1)^{th} step and N^{th} step program processes (i.e., program processes of the last two steps) may correspond to the 1^{st} step and 2^{nd} step program processes, respectively.

As an example, FIGS. 22 and 23 illustrate a two-step program process on a page of PLCs, each of which may fall in one of 32 states including erase state E and 1^{st} to 32^{nd} program states P1 to P31. The two-step program process may comprise 1^{st} step and 2^{nd} step program processes. FIGS. 22 and 23 illustrate results of the 1^{st} step and 2^{nd} step program processes, respectively.

During the 1^{st} step program process on the PLC page, the storage device 130 may inhibit programming of the PLCs for target threshold voltages of higher levels while applying program pulses to the PLCs for target threshold voltages of lower levels. Upon completion of the 1^{st} step program process on the PLC page, the PLCs may fall in one of 16 states including erase state E and 1^{st} to 15^{th} program states P1′ to P15′ as illustrated in FIG. 22. Then, upon completion of the 2^{nd} step program process on the PLC page, the PLCs may fall in one of 32 states including erase state E and 1^{st} to 32^{nd} program states P1 to P31 as illustrated in FIG. 23.

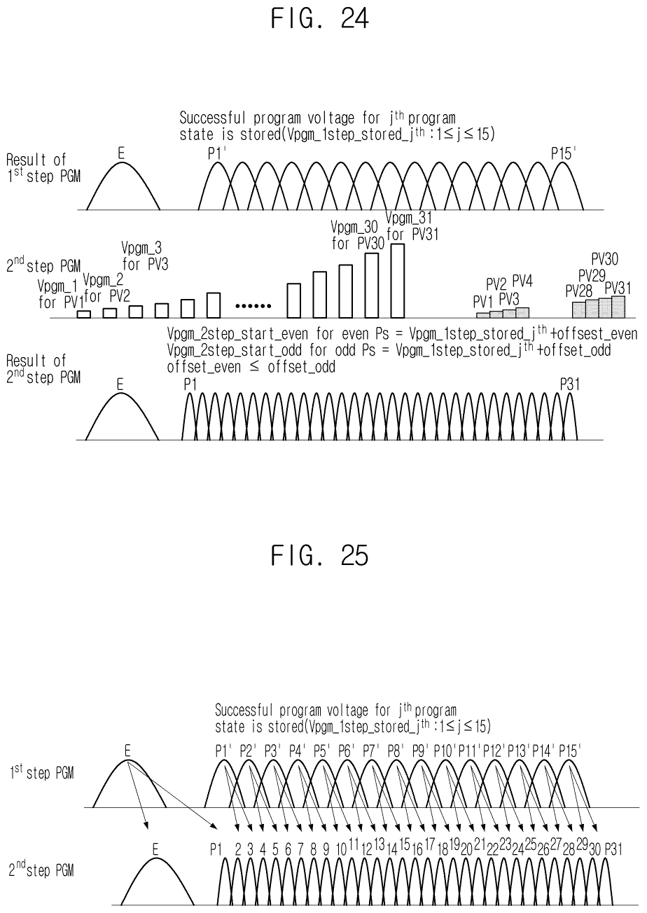

FIG. 24 is a diagram illustrating a two-step program process as an example of a multi-step program process according to an embodiment of the present invention.

Referring to FIG. 24, according to the present invention, during the two-step program process as an example of the multi-step program process, the 1^{st} step program process (“1^{st} step PGM” in FIG. 24) may be performed through the conventional program-verification scheme (i.e., the repeating of the alternation of a program pulse application operation and one or more verification operations) and the 2^{nd} step program process (“2^{nd} step PGM” in FIG. 24) may be performed through the one or more program loops each comprising the series of consecutive program pulse application operations and the series of consecutive verification operations.

During the 1^{st} step program process, one or more conventional program loops may be performed to the cells according to an incremental step pulse program (ISPP) scheme. Each of the conventional program loops comprises a single program pulse application operation and one or more verification operations. Each of the cells may be programmed to a target program level corresponding to a target program state and may be verified as programmed for the target program state at any of the plurality of conventional program loops.

For example, a cell is programmed and verified as programmed for a j^{th} program level Vpgm_1step_stored_j^{th} corresponding to a target program state at a particular one among the plurality of conventional program loops within the 1^{st} step program process. For example, the ‘j’ may be a natural number ranging from 1 to 15 in the example of FIG. 24. The range of “j” depends on the number of program states, to which the cells are supposed to belong during the 1^{st} step program process.

According to the present invention, during the 1^{st} step program process, the value of j^{th} program level Vpgm_1step_stored_j^{th} may be stored in any memory unit such as the storage device 130, a host system or the control logic 250. In the same manner, when each and every cell is programmed and verified as programmed for a corresponding program level Vpgm_1step_stored_j^{th} (1≤j≤maximum number of program states) corresponding to a corresponding program state during the 1^{st} step program process, each and every program level Vpgm_1step_stored_j^{th} may be stored in the memory unit.

In the example of FIG. 24 where the cells are supposed to belong to any of 16 number of states including the erase state E and 15 number of program states P1′ to P15′ during the 1^{st} step program process, 15 number of the program levels Vpgm_1step_stored_j^{th} (j=1 to 15) may be stored in the memory unit as a result of the 1^{st} step program process.

In the example of FIG. 24 where the cells, which are belonging to any of 16 number of states (the erase state E and 15 number of program states P1′ to P15′) as a result of the 1^{st} step program process, may be supposed to belong to any of 32 number of states including the erase state E and 31 number of program states P1 to P31, one or more program loops may be performed to the cells of the program states P1′ to P15′ in order to program the cells to belong to the erase state E and the 31 number of program states P1 to P31 during the 2^{nd} step program process. Each of the program loops comprises the series of consecutive program pulse application operations and the series of consecutive verification operations.

During the series of consecutive program pulse application operations within the 1^{st} one of the plural program loops in the 2^{nd} step program process, each of the series of consecutive program pulses Vpgm_2step_start_i (i=1 to 31) may be determined based on the 15 number of the program levels Vpgm_1step_stored_j^{th} (j=1 to 15), which are stored in the memory unit as a result of the 1^{st} step program process. The value of “i” depends on the number of program states, to which the cells are supposed to belong during each of the 1^{st} step program process and the 2^{nd} step program process.

In an embodiment, as the series of consecutive program pulse application operations proceed within subsequent ones to the 1^{st} one among the plural program loops, each of the series of consecutive program pulses Vpgm_2step_start_i (i=1 to 31) sequentially step up by an incremental step to program the cells from the lowest program state P1 to the highest program state P31, as discussed with reference to the above described first embodiment.

In an embodiment, as the series of consecutive program pulse application operations proceed within subsequent ones to the 1^{st} one among the plural program loops, each of the series of consecutive program pulses Vpgm_2step_start_i (i=1 to 31) sequentially step down by a decremental step to program the cells from the highest program state P31 to the lowest program state P1, as discussed with reference to the second embodiment.

The program states (“P1′” to “P15” in FIG. 24), to which the cells are supposed to belong during the 1^{st} step program process, may be different from the program states (“P1” to “P15” in FIG. 24), to which the cells are supposed to belong during the 2^{nd} step program process. Accordingly, the program levels, which the cells are supposed to have during the 1^{st} step program process, may be different from the program levels, which the cells are supposed to have during the 2^{nd} step program process.

Hereinafter, described are examples of determining, during the 1^{st} one of the plural program loops within the 2^{nd} step program process, each of the series of consecutive program pulses Vpgm_2step_start_i based on the program levels Vpgm_1step_stored_j^{th}, which are stored in the memory unit as a result of the 1^{st} step program process.

FIG. 25 is a diagram illustrating an example where the cells are supposed to belong to any of 16 number of states including the erase state E and 15 number of program states P1′ to P15′ during the 1^{st} step program process and are supposed to belong to any of 32 number of states including the erase state E and 31 number of program states P1 to P31 during the 2^{nd} step program process according to embodiments of the present invention.

Referring to FIG. 25, the 15 number of the program levels Vpgm_1step_stored_j^{th} (j=1 to 15) may be stored in the memory unit as a result of the 1^{st} step program process.

Referring to FIG. 25, during the 2^{nd} step program process, one or more program loops may be performed to the cells of the program states P1′ to P15′ in order to program the cells to belong to the erase state E and the 31 number of program states P1 to P31. Each of the program loops comprises the series of consecutive program pulse application operations and the series of consecutive verification operations.

During the series of consecutive program pulse application operations within the 1^{st} one of the plural program loops in the 2^{nd} step program process, each of the series of consecutive program pulses may be determined based on the 15 number of the program levels Vpgm_1step_stored_j^{th} (j=1 to 15), as shown in equation group 1.

$$Vpgm\_ 2 step\_start \_P1 for P 1 = Vpgm\_ 1 step\_stored {\_j}^{th} ( j = 2 ) - offset\_P1 \qquad [ Equation group 1 ]$$

$$Vpgm\_ 2 step\_start \_even ( even = 2 * j ) for even Ps = Vpgm\_ 1 step\_stored {\_j}^{th} + offset\_even$$

$$Vpgm\_ 2 step\_start \_odd ( odd = 2 * j + 1 ) for odd Ps = Vpgm\_ 1 step\_stored {\_j}^{th} + offset\_odd$$

$$offset\_even \leq offset\_odd$$

In equation group 1, the definitions are as follows.

“Vpgm_2step_start for P1” represents the program level of the program pulse to be applied to the cells of the program state P1 during the 1^{st} program loop of the 2^{nd} step program process.

“Vpgm_2step_start_P1” represents the program level of a program pulse to be applied to cells of P1 program states divided from erase status cells.

“offset_P1” is set to make “Vpgm_2step_start_P1” lower than Vpgm_2step_start_P2.

“Vpgm_2step_start_even” represents the program level of the program pulse to be applied to the cells of the even program states, where an even number is defined as 2j, during the 1^{st} program loop of the 2^{nd} step program process.

“Vpgm_1step_stored_j^{th}” represents the j^{th} program level, to which the cells are programmed and verified as programmed for the j^{th} program state Pj′ during the 1^{st} step program process.

“offset_even” represents the offset voltage level for the even program states at the 1^{st} program loop of the 2^{nd} step program process.

“Vpgm_2step_start_odd” represents the program level of the program pulse to be applied to the cells of the odd program states, where an odd number is defined as 2j+1, during the 1^{st} program loop of the 2^{nd} step program process.

“offset_odd” represents the offset voltage level for the odd program states at the 1^{st} program loop of the 2^{nd} step program process.

“offset_even” and “offset_odd” may be set to be variable with the j^{th} program level as denoted like “offset_even_j^{th}” and “offset_odd_j^{th}”.

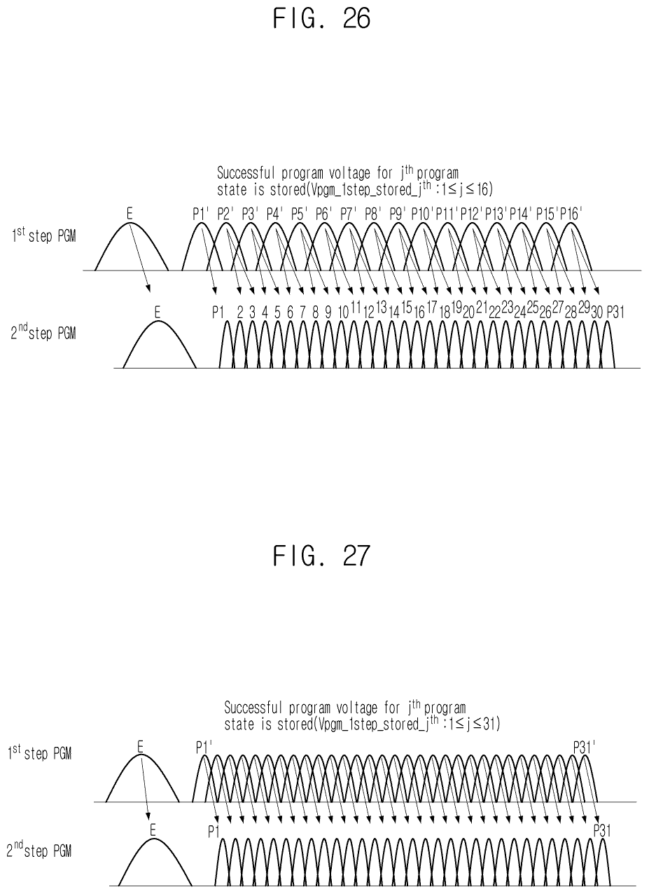

FIG. 26 is a diagram illustrating an example where the cells are supposed to belong to any of 17 number of states including the erase state E and 16 number of program states P1′ to P16′ during the 1^{st} step program process and are supposed to belong to any of 32 number of states including the erase state E and 31 number of program states P1 to P31 during the 2^{nd} step program process according to embodiments of the present invention.

Referring to FIG. 26, the 16 number of the program levels Vpgm_1step_stored_j^{th} (j=1 to 16) may be stored in the memory unit as a result of the 1^{st} step program process.

Referring to FIG. 26, during the 2^{nd} step program process, one or more program loops may be performed to the cells of the program states P1′ to P16′ in order to program the cells to belong to the erase state E and the 31 number of program states P1 to P31. Each of the program loops comprises the series of consecutive program pulse application operations and the series of consecutive verification operations.

During the series of consecutive program pulse application operations within the 1^{st} one of the plural program loops in the 2^{nd} step program process, each of the series of consecutive program pulses may be determined according to the 16 number of the program levels Vpgm_1step_stored_j^{th} (j=1 to 16), as shown in equation group 2.

$$Vpgm\_ 2 step\_start for P 1 = Vpgm\_ 1 step\_stored \_ {1}^{st} + offset\_ 1 \qquad [ Equation group 2 ]$$

$$Vpgm\_ 2 step\_start \_even ( even = 2 * j - 2 ) for even Ps = Vpgm\_ 1 step\_stored {\_j}^{th} + offset\_even$$

$$Vpgm\_ 2 step\_start \_odd ( odd = 2 * j - 1 ) for odd Ps = Vpgm\_ 1 step\_stored {\_j}^{th} + offset\_odd$$

$$offset\_even \leq offset\_odd ,$$

In equation group 2, the definitions are as follows.

“Vpgm_2step_start for P1” represents the program level of the program pulse to be applied to the cells of the program state P1 during the 1^{st} program loop of the 2^{nd} step program process.

“Vpgm_1step_stored_1^{st}” represents the program level, to which the cells are programmed and verified as programmed for the 1^{st} program state P1′ during the 1^{st} step program process.

“offset_1” represents the offset voltage level for the program state P1 at the 1^{st} program loop of the 2^{nd} step program process.

“Vpgm_2step_start_even” represents the program level of the program pulse to be applied to the cells of the even program states, where an even number is defined as 2j−2, during the 1^{st} program loop of the 2^{nd} step program process.

“Vpgm_1step_stored_j^{th}” represents the j^{th} program level, to which the cells are programmed and verified as programmed for the j^{th} program state Pj′ during the 1^{st} step program process.

“offset_even” represents the offset voltage level for the even program states at the 1^{st} program loop of the 2^{nd} step program process.

“Vpgm_2step_start_odd” represents the program level of the program pulse to be applied to the cells of the odd program states, where an odd number is defined as 2j−1, during the 1^{st} program loop of the 2^{nd} step program process.

“offset_odd” represents the offset voltage level for the odd program states at the 1^{st} program loop of the 2^{nd} step program process.

“offset_even” and “offset_odd” may be set to be variable with the j^{th} program level as denoted like “offset_even_j^{th}” and “offset_odd_j^{th}”.

FIG. 27 is a diagram illustrating an example where the cells are supposed to belong to any of 32 number of states including the erase state E and 31 number of program states P1′ to P31′ during the 1^{st} step program process and are supposed to belong to any of 32 number of states including the erase state E and 31 number of program states P1 to P31 during the 2^{nd} step program process according to embodiments of the present invention.

Referring to FIG. 27, the 31 number of the program levels Vpgm_1step_stored_j^{th} (j=1 to 31) may be stored in the memory unit as a result of the 1^{st} step program process.

Referring to FIG. 27, during the 2^{nd} step program process, one or more program loops may be performed to the cells of the program states P1′ to P31′ in order to program the cells to belong to the erase state E and the 31 number of program states P1 to P31. Each of the program loops comprises the series of consecutive program pulse application operations and the series of consecutive verification operations.

During the series of consecutive program pulse application operations within the 1^{st} one of the plural program loops in the 2^{nd} step program process, each of the series of consecutive program pulses may be determined according to the 16 number of the program levels Vpgm_1step_stored_j^{th} (j=1 to 31), as shown in equation group 3.

$$Vpgm\_ 2 step\_start {i}^{th} = Vpgm\_ 1 step\_stored {\_j}^{th} + offset \qquad [ Equation group 3 ]$$

$$i = j$$

In equation group 3, the definitions are as follows.

“Vpgm_2step_start_i^{th}” represents the program level of the program pulse to be applied to the cells of the i^{th} program state, where i=j, during the 1^{st} program loop of the 2^{nd} step program process.

“Vpgm_1step_stored_j^{th}” represents the j^{th} program level, to which the cells are programmed and verified as programmed during the 1^{st} step program process.

“offset” represents the offset voltage level for all program states at the 1^{st} program loop of the 2^{nd} step program process.

“offset” may be set to be variable with the j^{th} program level as denoted like “offset_j^{th}”.

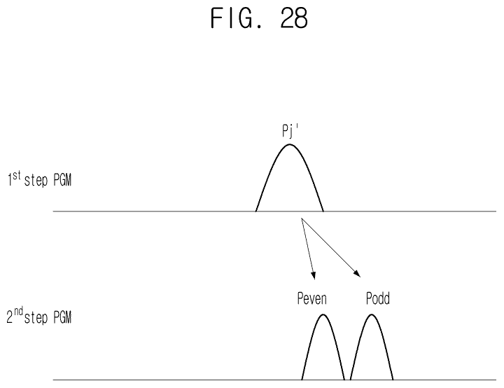

FIG. 28 is a diagram illustrating a general example where the cells are supposed to belong to any of (X+1) number of states including the erase state E and X number of program states P1′ to PX′ during the 1^{st} step program process and are supposed to belong to any of (Y+1) number of states including the erase state E and Y number of program states P1 to PY during the 2^{nd} step program process according to embodiments of the present invention.

FIG. 28 illustrates a cell distribution of representative program state Pj′ among the X number of program states P1′ to PX′, as a result of programming and verifying the cells as programmed for the X number of the program levels Vpgm_1step_stored_j^{th} (j=1 to X) during the 1^{st} step program process. The X number of the program levels Vpgm_1step_stored_j^{th} (j=1 to X) may be stored in the memory unit as a result of the 1^{st} step program process.

Referring to FIG. 28, during the 2^{nd} step program process, one or more program loops may be performed to the cells of the program states P1′ to PX′ in order to program the cells to belong to the erase state E and the Y number of program states P1 to PY. Each of the program loops comprises the series of consecutive program pulse application operations and the series of consecutive verification operations.

FIG. 28 illustrates cell distributions of representative program states Peven and Podd among the Y number of program states P1 to PY, as a result of programming the cells of the target program states Peven and Podd respectively corresponding to the program levels Vpgm_2step_start_even and Vpgm_2step_start_odd at the 1^{st} program loop of the 2^{nd} step program process.

During the series of consecutive program pulse application operations within the 1^{st} one of the plural program loops in the 2^{nd} step program process, each of the series of consecutive program pulses may be determined according to the X number of the program levels Vpgm_1step_stored_j^{th} (j=1 to X), as shown in equation group 4.

$$Vpgm\_ 2 step\_start \_even for even Ps = Vpgm\_ 1 step\_stored {\_j}^{th} + offset\_even \qquad [ Equation group 4 ]$$

$$Vpgm\_ 2 step\_start \_odd for odd Ps = Vpgm\_ 1 step\_stored {\_j}^{th} + offset\_odd$$

$$offset\_even \leq offset\_odd$$

In equation group 4, the definitions are as follows.

“Vpgm_2step_start_even” represents the program level of the program pulse to be applied to the cells of the even program states during the 1^{st} program loop of the 2^{nd} step program process.

“Vpgm_1step_stored_j^{th}” represents the j^{th} program level, to which the cells are programmed and verified as programmed for the j^{th} program state Pj′ during the 1^{st} step program process.

“offset_even” represents the offset voltage level for the even program states at the 1^{st} program loop of the 2^{nd} step program process.

“Vpgm_2step_start_odd” represents the program level of the program pulse to be applied to the cells of the odd program states during the 1^{st} program loop of the 2^{nd} step program process.

“offset_odd” represents the offset voltage level for the odd program states at the 1^{st} program loop of the 2^{nd} step program process.

“offset_even” and “offset_odd” may be set to be variable with the j^{th} program level as denoted like “offset_even_j^{th}” and “offset_odd_j^{th}”.

In equation group 4, the variables “Vpgm_2step_start_even” and “Vpgm_2step_start_odd” may be related to the variable “Vpgm_1step_stored_j^{th}” respectively along with the offsets “offset_even” and “offset_odd”. As the value “j” changes, all the values of the variables “Vpgm_2step_start_even”, “Vpgm_2step_start_odd”, “Vpgm_1step_stored_j^{th}”, “offset_even” and “offset_odd” may change, as shown above in equation groups 1 to 3.

Range of the value “j” depends on a number of program states P1′ to PX′, to which the cells are supposed to belong during the 1^{st} step program process. That is, the value “j” may be between one (1) and X.

As described above, during the series of consecutive program pulse application operations within the 1^{st} one of the plural program loops in the 2^{nd} step program process, each of the series of consecutive program pulses may be determined based on the 15 number of the program levels Vpgm_1step_stored_j^{th} (j=1 to 15), as shown in equation group 1. Multiple program states more than two states in the 2^{nd} step program process are divided from the J^{th} program state in the 1^{st} step program process according to a following equation group 5.

$$Vpgm\_ 2 step\_start {\_i}_{th} = Vpgm\_ 1 step\_stored {\_j}^{th} + offset\_i \_j ( at {J}_{th} program state ) \qquad [ Equation group 5 ]$$

In equation group 5, the definitions are as follows.

Index of “iₜₕ” varies from 1 to a total number of program states in the 2^{nd} step program process divided from the “Jₜₕ program state” in the 1^{st} step program process.

“offset_i_j” value increases with increasing i^{th} numbers at the specific “Jₜₕ program state” in the 1^{st} step program process.

“Vpgm_2step_start_iₜₕ” represents a program level of a program pulse to be applied to cells of program states during the 1^{st} program loop in the T^{th} step program process.

“Vpgm_1step_stored_j^{th}” represents the j^{th} program level in the 1^{st} step program process.

“offset_i_j” may be set to be variable with the j^{th} program level.

Although the foregoing embodiments have been illustrated and described in some detail for purposes of clarity and understanding, the present invention is not limited to the details provided. There are many alternative ways of implementing the invention, as one skilled in the art will appreciate in light of the foregoing disclosure. The disclosed embodiments are thus illustrative, not restrictive. The present invention is intended to embrace all modifications and alternatives of the disclosed embodiment. Furthermore, the disclosed embodiments may be combined to form additional embodiments.

Indeed, implementations of the subject matter and the functional operations described in the present disclosure can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any type of digital computer. Generally, a processor will receive instructions and data from a read only memory or a random-access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices. The processor and the memory can be supplemented by, or incorporated in, special purpose logic circuitry.

While the present disclosure contains many specifics, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments.

Only a few embodiments and examples are described and other embodiments, enhancements and variations can be made based on what is described and illustrated in the present disclosure.

What is claimed is:

1. A storage device comprising:
a group of non-volatile memory cells;
page buffers coupled to the non-volatile memory cells; and
a control circuit configured to perform one or more program loops on the group according to program data loaded on the page buffers, each of the program loops including a series of consecutive program pulse application operations and a series of consecutive verification operations, wherein:
the control circuit is configured to apply, during each of the series of consecutive program pulse application operations in each of the program loops, a selected program pulse to one or more non-volatile memory cells under a program-permission mode within the group while program-inhibiting remaining non-volatile memory cells under a program-inhibition mode within the group,
the selected program pulse is one among a series of consecutive program pulses to be applied to the group during the program pulse application operation,
the control circuit is further configured to determine, in between current and subsequent ones among the series of consecutive program pulse application operations, a selected one of the non-volatile memory cells as under the program-permission mode or the program-inhibition mode for the subsequent program pulse application operation by updating current program data currently staying loaded on a corresponding one of the page buffers for the current program pulse application operation, and
the control circuit updates the current program data by performing a logical operation on the current program data and reference data, which represents a target program level corresponding to a program pulse to be applied during the subsequent program pulse application operation.

2. The storage device of claim 1, wherein the levels of the program pulses sequentially step up by an incremental step over the respective program loops.

3. The storage device of claim 1, wherein:
the control circuit performs, during each of the program loops, the series of consecutive program pulse application operations by consecutively applying respective program pulses to the group, levels of the program pulses sequentially stepping up by an incremental step over the respective program pulse application operations, and
the control circuit performs, during each of the program loops, the series of consecutive verification operations by consecutively applying respective verification pulses to the group, levels of the verification pulses sequentially stepping up by an incremental step over the respective verification operations.

4. The storage device of claim 3, wherein:
the control circuit determines the selected memory cell as under the program-permission mode when a current program level is equal to the target program level as a result of the logical operation, and
the current program level is represented by the current program data.

5. The storage device of claim 3, wherein:
the control circuit determines the selected memory cell as under the program-permission mode when a current program level is higher than the target program level as a result of the logical operation, and
the current program level is represented by the current program data.

6. The storage device of claim 3, wherein the control circuit is further configured to perform, when one of the non-volatile memory cells is verified as programmed during a current one of the program loops, the series of consecutive program pulse application operations on the verified non-volatile memory cells while keeping the verified memory cell under the program-inhibition mode for subsequent program loops following the current program loop among the program loops.

7. The storage device of claim 3, wherein the control circuit is further configured to exclude, when one of the non-volatile memory cells is verified as programmed during a previous one of the program loops, the series of consecutive program pulse application operations on the verified memory cell during a current program loop subsequent to the previous program loop.

8. The storage device of claim 7, wherein the control circuit is further configured to perform again, when the verified memory cell is further verified as under-programmed during the current program loop, the series of consecutive program pulse application operations on the verified memory cell during a subsequent program loop following the current program loop.

9. The storage device of claim 3, wherein the control circuit is further configured to exclude, when one of the non-volatile memory cells is verified as programmed during a current one of the program loops, the series of consecutive verification operations on the verified memory cell during subsequent program loops following the current program loop among the program loops.

10. The storage device of claim 1, wherein:
the control circuit performs, during each of the program loops, the series of consecutive program pulse application operations by consecutively applying respective program pulses to the group, levels of the program pulses sequentially stepping down by a decremental step over the respective program pulse application operations, and
the control circuit performs, during each of the program loops, the series of consecutive verification operations by consecutively applying respective verification pulses to the group, levels of the verification pulses sequentially stepping up by an incremental step over the respective verification operations.

11. The storage device of claim 10, wherein:
the control circuit determines the selected memory cell as under the program-permission mode when a current program level is equal to the target program level as a result of the logical operation, and
the current program level is represented by the current program data.

12. The storage device of claim 10, wherein:
the control circuit determines the selected memory cell as under the program-permission mode when a current program level is higher than the target program level as a result of the logical operation, and
the current program level is represented by the current program data.

13. The storage device of claim 10, wherein the control circuit is further configured to perform, when one of the non-volatile memory cells is verified as programmed during a current one of the program loops, the series of consecutive program pulse application operations on the verified non-volatile memory cells while keeping the verified memory cell under the program-inhibition mode for subsequent program loops following the current program loop among the program loops.

14. The storage device of claim 10, wherein the control circuit is further configured to exclude, when one of the non-volatile memory cells is verified as programmed during a previous one of the program loops, the series of consecutive program pulse application operations on the verified memory cell during a current program loop subsequent to the previous program loop.

15. The storage device of claim 14, wherein the control circuit is further configured to perform again, when the verified memory cell is further verified as under-programmed during the current program loop, the series of consecutive program pulse application operations on the verified memory cell during a subsequent program loop following the current program loop.

16. The storage device of claim 10, wherein the control circuit is further configured to exclude, when one of the non-volatile memory cells is verified as programmed during a current one of the program loops, the series of consecutive verification operations on the verified memory cell during subsequent program loops following the current program loop among the program loops.

17. A storage device comprising:
a group of non-volatile memory cells;
page buffers coupled to the non-volatile memory cells; and
a control circuit configured to:
perform a (T−1)^{th} step program process on the group, T being a natural number of two (2) or greater; and
perform a T^{th} step program process on the group upon completion of the (T−1)^{th} step program process, wherein:
the T^{th} step program process includes one or more program loops on the group according to program data loaded on the page buffers, each of the program loops including a series of consecutive program pulse application operations and a series of consecutive verification operations,
the control circuit is configured to apply, during each of the series of consecutive program pulse application operations in each of the program loops, a selected program pulse to one or more non-volatile memory cells under a program-permission mode within the group while program-inhibiting remaining non-volatile memory cells under a program-inhibition mode within the group,
the selected program pulse is one among a series of consecutive program pulses to be applied to the group during the program pulse application operation,
the control circuit is further configured to determine, in between current and subsequent ones among the series of consecutive program pulse application operations, a selected one of the non-volatile memory cells as under the program-permission mode or the program-inhibition mode for the subsequent program pulse application operation by updating current program data currently staying loaded on a corresponding one of the page buffers for the current program pulse application operation, and
the control circuit updates the current program data by performing a logical operation on the current program data and reference data, which represents a target program level corresponding to a program pulse to be applied during the subsequent program pulse application operation.

18. The storage device of claim 17, wherein the levels of the program pulses sequentially step up by an incremental step over the respective program loops.

19. The storage device of claim 17, wherein:
the control circuit performs, during each of the program loops, the series of consecutive program pulse application operations by consecutively applying respective program pulses to the group, levels of the program pulses sequentially stepping up by an incremental step over the respective program pulse application operations, and
the control circuit performs, during each of the program loops, the series of consecutive verification operations by consecutively applying respective verification pulses to the group, levels of the verification pulses sequentially stepping up by an incremental step over the respective verification operations.

20. The storage device of claim 19, wherein:
the control circuit determines the selected memory cell as under the program-permission mode when a current program level is equal to the target program level as a result of the logical operation, and
the current program level is represented by the current program data.

21. The storage device of claim 19, wherein:
the control circuit determines the selected memory cell as under the program-permission mode when a current program level is higher than the target program level as a result of the logical operation, and
the current program level is represented by the current program data.

22. The storage device of claim 19, wherein the control circuit is further configured to perform, when one of the non-volatile memory cells is verified as programmed during a current one of the program loops, the series of consecutive program pulse application operations on the verified non-volatile memory cells while keeping the verified memory cell under the program-inhibition mode for subsequent program loops following the current program loop among the program loops.

23. The storage device of claim 19, wherein the control circuit is further configured to exclude, when one of the non-volatile memory cells is verified as programmed during a previous one of the program loops, the series of consecutive program pulse application operations on the verified memory cell during a current program loop subsequent to the previous program loop.

24. The storage device of claim 23, wherein the control circuit is further configured to perform again, when the verified memory cell is further verified as under-programmed during the current program loop, the series of consecutive program pulse application operations on the verified memory cell during a subsequent program loop following the current program loop.

25. The storage device of claim 19, wherein the control circuit is further configured to exclude, when one of the non-volatile memory cells is verified as programmed during a current one of the program loops, the series of consecutive verification operations on the verified memory cell during subsequent program loops following the current program loop among the program loops.

26. The storage device of claim 17, wherein:
the control circuit performs, during each of the program loops, the series of consecutive program pulse application operations by consecutively applying respective program pulses to the group, levels of the program pulses sequentially stepping down by a decremental step over the respective program pulse application operations, and
the control circuit performs, during each of the program loops, the series of consecutive verification operations by consecutively applying respective verification pulses to the group, levels of the verification pulses sequentially stepping up by an incremental step over the respective verification operations.

27. The storage device of claim 26, wherein:
the control circuit determines the selected memory cell as under the program-permission mode when a current program level is equal to the target program level as a result of the logical operation, and
the current program level is represented by the current program data.

28. The storage device of claim 26, wherein:
the control circuit determines the selected memory cell as under the program-permission mode when a current program level is higher than the target program level as a result of the logical operation, and
the current program level is represented by the current program data.

29. The storage device of claim 26, wherein the control circuit is further configured to perform, when one of the non-volatile memory cells is verified as programmed during a current one of the program loops, the series of consecutive program pulse application operations on the verified non-volatile memory cells while keeping the verified memory cell under the program-inhibition mode for subsequent program loops following the current program loop among the program loops.

30. The storage device of claim 26, wherein the control circuit is further configured to exclude, when one of the non-volatile memory cells is verified as programmed during a previous one of the program loops, the series of consecutive program pulse application operations on the verified memory cell during a current program loop subsequent to the previous program loop.

31. The storage device of claim 30, wherein the control circuit is further configured to perform again, when the verified memory cell is further verified as under-programmed during the current program loop, the series of consecutive program pulse application operations on the verified memory cell during a subsequent program loop following the current program loop.

32. The storage device of claim 26, wherein the control circuit is further configured to exclude, when one of the non-volatile memory cells is verified as programmed during a current one of the program loops, the series of consecutive verification operations on the verified memory cell during subsequent program loops following the current program loop among the program loops.

33. The storage device of claim 26, wherein the (T−1)^{th} step program process includes one or more conventional program loops each including a single program pulse application operation and one or more verification operation according to an incremental step pulse program (ISPP) scheme.

34. The storage device of claim 33, wherein:
the (T−1)^{th} step program process includes storing a value of j^{th} program level when a selected one of the non-volatile memory cells is verified as programmed for a j^{th} program level during the conventional program loops, and
“j” is a natural number ranging from one (1) to J, “J” being a maximum number of program states, to which the non-volatile memory cells within the group are supposed to belong during the (T−1)^{th} step program process.

35. The storage device of claim 34, wherein the T^{th} step program process includes determining, during the series of consecutive program pulse application operations within a 1^{st} one of the plural program loops, a program level of each of the series of consecutive program pulses based on the J number of stored program levels according to a following equation group 1:
$$Vpgm\_ 2 step\_start \_P1 for P 1 = Vpgm\_ 1 step\_stored {\_j}^{th} ( j = 2 ) - offset\_P1 \qquad [ Equation group 1 ]$$
$$Vpgm\_ 2 step\_start \_even ( even = 2 * j ) for even Ps = Vpgm\_ 1 step\_stored {\_j}^{th} + offset\_even$$
$$Vpgm\_ 2 step\_start \_odd ( odd = 2 * j + 1 ) for odd Ps = Vpgm\_ 1 step\_stored {\_j}^{th} + offset\_odd$$
$$offset\_even \leq offset\_odd ,$$
wherein:
“Vpgm_2step_start for P1” represents the program level of a program pulse to be applied to cells of a first program state during the 1^{st} program loop,
“Vpgm_2step_start_P1” represents the program level of a program pulse to be applied to cells of P1 program states divided from erase status cells,
“offset_P1” is set to make “Vpgm_2step_start_P1” lower than Vpgm_2step_start_P2,
“Vpgm_2step_start_even” represents the program level of a program pulse to be applied to cells of even program states, an even number being defined as 2j, during the 1^{st} program loop,
“Vpgm_1step_stored_j^{th}” represents the j^{th} program level,
“offset_even” represents an offset voltage level for the even program states at the 1^{st} program loop,
“Vpgm_2step_start_odd” represents the program level of a program pulse to be applied to cells of odd program states, an odd number being defined as 2+1, during the 1^{st} program loop, and
“offset_odd” represents an offset voltage level for the odd program states at the 1^{st} program loop.

36. The storage device of claim 35, wherein “offset_even” and “offset_odd” are set to be variable with the j^{th} program level as denoted like “offset_even_j^{th}” and “offset_odd_j^{th}”.

37. The storage device of claim 34, wherein the T^{th} step program process includes determining, during the series of consecutive program pulse application operations within a 1^{st} one of the plural program loops, a program level of each of the series of consecutive program pulses based on the J number of stored program levels according to a following equation group 2:
$$Vpgm\_ 2 step\_start for P 1 = Vpgm\_ 1 step\_stored \_ {1}^{st} + offset\_ 1 \qquad [ Equation group 2 ]$$
$$Vpgm\_ 2 step\_start \_even ( even = 2 * j - 2 ) for even Ps = Vpgm\_ 1 step\_stored {\_j}^{th} + offset\_even$$
$$Vpgm\_ 2 step\_start \_odd ( odd = 2 * j - 1 ) for odd Ps = Vpgm\_ 1 step\_stored {\_j}^{th} + offset\_odd$$
$$offset\_even \leq offset\_odd ,$$
wherein:
“Vpgm_2step_start for P1” represents the program level of a program pulse to be applied to cells of a first program state during the 1^{st} program loop,
“Vpgm_1step_stored_1^{st}” represents the j^{th} program level with j=1,
“offset_1” represents an offset voltage level for the first program state at the 1^{st} program loop,
“Vpgm_2step_start_even” represents the program level of a program pulse to be applied to cells of even program states, an even number being defined as 2j−2, during the 1^{st} program loop,
“Vpgm_1step_stored_j^{th}” represents the j^{th} program level,
“offset_even” represents an offset voltage level for the even program states at the 1^{st} program loop,
“Vpgm_2step_start_odd” represents the program level of a program pulse to be applied to cells of odd program states, an odd number being defined as 2j−1, during the 1^{st} program loop, and
“offset_odd” represents an offset voltage level for the odd program states at the 1^{st} program loop.

38. The storage device of claim 37, wherein “offset_even” and “offset_odd” are set to be variable with the j^{th} program level as denoted like “offset_even_j^{th}” and “offset_odd_j^{th}”.

39. The storage device of claim 34, wherein the T^{th} step program process includes determining, during the series of consecutive program pulse application operations within a 1^{st} one of the plural program loops, a program level of each of the series of consecutive program pulses based on the J number of stored program levels according to a following equation group 3:
$$Vpgm\_ 2 step\_start {i}^{th} = Vpgm\_ 1 step\_stored {\_j}^{th} + offset \qquad [ Equation group 3 ]$$
$$i = j ,$$
wherein:
“Vpgm_2step_start_i^{th}” represents the program level of a program pulse to be applied to cells of an i^{th} program state during the 1^{st} program loop,
“Vpgm_1step_stored_j^{th}” represents the j^{th} program level, and
“offset” represents an offset voltage level for all program states at the 1^{st} program loop.

40. The storage device of claim 39, wherein “offset” is set to be variable with the j^{th} program level as denoted like “offset_j^{th}”.

41. The storage device of claim 34, wherein the T^{th} step program process includes determining, during the series of consecutive program pulse application operations within a 1^{st} one of the plural program loops, program level of each of the series of consecutive program pulses based on the J number of stored program levels according to a following equation group 4:
$$Vpgm\_ 2 step\_start \_even for even Ps = Vpgm\_ 1 step\_stored {\_j}^{th} + offset\_even \qquad [ Equation group 4 ]$$
$$Vpgm\_ 2 step\_start \_odd for odd Ps = Vpgm\_ 1 step\_stored {\_j}^{th} + offset\_odd$$
$$offset\_even \leq offset\_odd ,$$
wherein:
“Vpgm_2step_start_even” represents a program level of a program pulse to be applied to cells of even program states during the 1^{st} program loop,
“Vpgm_1step_stored_j^{th}” represents the j^{th} program level,
“offset_even” represents an offset voltage level for the even program states at the 1^{st} program loop,
“Vpgm_2step_start_odd” represents the program level of a program pulse to be applied to the cells of odd program states during the 1^{st} program loop, and
“offset_odd” represents an offset voltage level for the odd program states at the 1^{st} program loop.

42. The storage device of claim 41, wherein “offset_even” and “offset_odd” are set to be variable with the j^{th} program level as denoted like “offset_even_j^{th}” and “offset_odd_j^{th}”.

43. The storage device of claim 34, wherein:
the T^{th} step program process includes determining, during the series of consecutive program pulse application operations within a 1^{st} one of the plural program loops, a program level of each of the series of consecutive program pulses based on the J number of stored program levels, and
multiple program states more than two states in the T^{th} step program process are divided from the J^{th} program state in the (T−1)^{th} step program process according to a following equation group 5:
$$Vpgm\_ 2 step\_start {\_i}_{th} = Vpgm\_ 1 step\_stored {\_j}^{th} + offset\_i \_j ( at {J}_{th} program state ) , \qquad [ Equation group 5 ]$$
wherein:
index of “iₜₕ” varies from 1 to a total number of program states in the T^{th} step program process divided from the “Jₜₕ program state” in the (T−1)^{th} step program process,
“offset_i_j” value increases with increasing i^{th} numbers at the specific “Jₜₕ program state” in the (T−1)^{th} step program process,
“Vpgm_2step_start_i^{th}” represents a program level of a program pulse to be applied to cells of program states during the 1^{st} program loop in the T^{th} step program process,
“Vpgm_1step_stored_j^{th}” represents the j^{th} program level in the the (T−1)^{th} step program process.

44. The storage device of claim 43, wherein “offset_i_j” is set to be variable with the j^{th} program level.
